(19) United States
(12) Patent Application Publication
(10) Pub. No.: US 2023/0097091 A1
(43) Pub. Date: Mar. 30, 2023

(54) PHOTOELECTRIC CONVERSION APPARATUS

(71) Applicant: CANON KABUSHIKI KAISHA, Tokyo (JP)

(72) Inventors: Kazuhiro Morimoto, Kanagawa (JP); Junji Iwata, Tokyo (JP)

(21) Appl. No.: 17/932,952

(22) Filed: Sep. 16, 2022

(30) Foreign Application Priority Data
Sep. 22, 2021 (JP) 2021-154432

(51) Int. Cl. H01L 31/107; H01L 27/146

(52) U.S. Cl. CPC H01L 31/107; H01L 27/1463; H01L 27/14636

(57) ABSTRACT

A photoelectric conversion apparatus includes an avalanche diode arranged in a semiconductor layer having a first surface and a second surface facing the first surface. The avalanche diode includes a first semiconductor region of a first conductivity type, which is arranged at a first depth, a second semiconductor region of a second conductivity type, which is arranged at a second depth deeper than the first depth with respect to the second surface, a third semiconductor region provided in contact with an end of the first semiconductor region in a planar view from the second surface, a first wiring portion connected to the first semiconductor region, and a second wiring portion connected to the second semiconductor region. In a planar view from the second surface, at least part of a boundary between an insulating film and the second wiring portion that faces the first wiring portion overlaps the third semiconductor region and does not overlap the first semiconductor region.

### BACKGROUND OF THE INVENTION

### Field of the Invention

The present invention relates to a photoelectric conversion apparatus and a photoelectric conversion system.

### Description of the Related Art

There is a photoelectric conversion apparatus with quantum conversion efficiency improved by the elongated optical path length of incident light in the photoelectric conversion element. The optical path length of incident light is elongated by a light reflector provided in the wiring layer reflecting incident light that has passed through the semiconductor substrate. U.S. Pat. Application Publication No. 2020/0286946 discusses a single-photon avalanche diode (SPAD) provided with an anode wire as a light reflector. Similarly, U.S. Pat. Application Publication No. 2019/0181177 discusses an SPAD including an extended anode wire.

### SUMMARY OF THE INVENTION

According to an aspect of the present invention, a photoelectric conversion apparatus includes an avalanche diode arranged in a semiconductor layer having a first surface and a second surface facing the first surface. The avalanche diode includes a first semiconductor region of a first conductivity type, which is arranged at a first depth, a second semiconductor region of a second conductivity type, which is arranged at a second depth deeper than the first depth with respect to the second surface, a third semiconductor region provided in contact with an end of the first semiconductor region in a planar view from the second surface, a first wiring portion connected to the first semiconductor region, and a second wiring portion connected to the second semiconductor region. In a planar view from the second surface, at least part of a boundary between an insulating film and the second wiring portion that faces the first wiring portion overlaps the third semiconductor region and does not overlap the first semiconductor region.

According to another aspect of the present invention, a photoelectric conversion apparatus includes a plurality of avalanche diodes arranged in a semiconductor layer having a first surface and a second surface facing the first surface. The avalanche diode includes a first semiconductor region of a first conductivity type, which is arranged at a first depth, a second semiconductor region of a second conductivity type, which is arranged at a second depth deeper than the first depth with respect to the second surface, a third semiconductor region provided in contact with an end of the first semiconductor region in a planar view from the second surface, a first wiring portion connected to the first semiconductor region, and a second wiring portion connected to the second semiconductor region. In a planar view from the second surface, at least part of a line internally dividing, into equal distances, a distance between a boundary between the first wiring portion and an insulating film and a boundary between the second wiring portion and the insulating film overlaps the third semiconductor region and does not overlap the first semiconductor region.

According to yet another aspect of the present invention, a photoelectric conversion apparatus includes an avalanche diode arranged in a semiconductor layer having a first surface and a second surface facing the first surface. The avalanche diode includes a first semiconductor region of a first conductivity type, which is arranged at a first depth, an avalanche multiplication region formed between the first semiconductor region and a second semiconductor region of a second conductivity type, which is arranged at a second depth deeper than the first depth with respect to the second surface, an electric field mitigation region surrounding the avalanche multiplication region in a planar view from the second surface, a first wiring portion connected to the first semiconductor region, and a second wiring portion connected to the second semiconductor region. In a planar view from the second surface, at least part of a boundary between an insulating film and the second wiring portion that faces the first wiring portion overlaps the electric field mitigation region.

According to yet another aspect of the present invention, a photoelectric conversion apparatus includes an avalanche diode arranged in a semiconductor layer having a first surface and a second surface facing the first surface. The avalanche diode includes a first semiconductor region of a first conductivity type, which is arranged at a first depth, an avalanche multiplication region formed between the first semiconductor region and a second semiconductor region of a second conductivity type, which is arranged at a second depth deeper than the first depth with respect to the second surface, an electric field mitigation region surrounding the avalanche multiplication region in a planar view from the second surface, a first wiring portion connected to the first semiconductor region, and a second wiring portion connected to the second semiconductor region. In a planar view from the second surface, at least part of a line internally dividing, into equal distances, a distance between a boundary between the first wiring portion and an insulating film, and a boundary between the second wiring portion and the insulating film overlaps the electric field mitigation region.

Further features of the present invention will become apparent from the following description of exemplary embodiments with reference to the attached drawings.

### BRIEF DESCRIPTION OF THE DRAWINGS

FIG. 1 is a schematic diagram of a photoelectric conversion apparatus according to one or more exemplary embodiments.

FIG. 2 is a schematic diagram of a photodiode (PD) substrate of a photoelectric conversion apparatus according to one or more exemplary embodiments.

FIG. 3 is a schematic diagram of a circuit substrate of a photoelectric conversion apparatus according to one or more exemplary embodiments.

FIG. 4 illustrates a configuration example of a pixel circuit of a photoelectric conversion apparatus according to one or more exemplary embodiments.

FIGS. 5A to 5C are schematic diagrams illustrating driving of a pixel circuit of a photoelectric conversion apparatus according to one or more exemplary embodiments.

FIG. 6 is a cross-sectional view of a photoelectric conversion element according to a first exemplary embodiment.

FIGS. 7A and 7B are plan views of the photoelectric conversion element according to the first exemplary embodiment.

FIG. 8 is a potential graph of the photoelectric conversion element according to the first exemplary embodiment.

FIG. 9 illustrates a comparative example of the photoelectric conversion element according to the first exemplary embodiment.

FIGS. 10A and 10B are potential graphs of the photoelectric conversion element according to the first exemplary embodiment.

FIG. 11 is a cross-sectional view of a photoelectric conversion element according to a second exemplary embodiment.

FIGS. 12A and 12B are plan views of the photoelectric conversion element according to the second exemplary embodiment.

FIG. 13 is a cross-sectional view of a photoelectric conversion element according to a modified example of the second exemplary embodiment.

FIG. 14 is a cross-sectional view of a photoelectric conversion element according to a third exemplary embodiment.

FIGS. 15A and 15B are plan views of the photoelectric conversion element according to the third exemplary embodiment.

FIG. 16 is a cross-sectional view of a photoelectric conversion element according to a fourth exemplary embodiment.

FIGS. 17A and 17B are plan views of the photoelectric conversion element according to the fourth exemplary embodiment.

FIG. 18 is a cross-sectional view of a photoelectric conversion element according to a fifth exemplary embodiment.

FIGS. 19A and 19B are plan views of the photoelectric conversion element according to the fifth exemplary embodiment.

FIG. 20 is a functional block diagram of a photoelectric conversion system according to a sixth exemplary embodiment.

FIGS. 21A and 21B are functional block diagrams of a photoelectric conversion system according to a seventh exemplary embodiment.

FIG. 22 is a functional block diagram of a photoelectric conversion system according to an eighth exemplary embodiment.

FIG. 23 is a functional block diagram of a photoelectric conversion system according to a ninth exemplary embodiment.

FIGS. 24A and 24B are functional block diagrams of a photoelectric conversion system according to a tenth exemplary embodiment.

### DESCRIPTION OF THE EMBODIMENTS

The following exemplary embodiments will be described for the purpose of embodying the technical idea of the present invention, and are not intended to limit the present invention. The sizes and the positional relationships of members illustrated in the drawings are exaggerated for a clear description in some cases. In the following description, the like numbers refer to like components, and the description thereof will be omitted in some cases.

Hereinafter, some exemplary embodiments of the present invention will be described in detail with reference to the drawings. In the following description, terms (e.g., “up”, “down”, “right”, “left”, and other terms including these terms) indicating specific directions and positions are used as appropriate. These terms are used to facilitate the understanding of the exemplary embodiments to be described with reference to the drawings. The technical scope of the present invention is not limited by the meanings of these terms.

In this specification, a “planar view” refers to a view in the direction vertical to the light incidence surface of a semiconductor layer. A cross section refers to a surface in the direction vertical to the light incidence surface of a semiconductor layer. When the light incidence surface of the semiconductor layer is a microscopically rough surface, a planar view is defined based on the light incidence surface of a semiconductor layer viewed macroscopically.

In the following description, the anode of an avalanche photodiode (APD) is set to a fixed potential, and signals are taken out from its cathode. Thus, the semiconductor region of a first conductivity type in which charges of the same polarity as the polarity of signal charges are major carriers is an N-type semiconductor region, and the semiconductor region of a second conductivity type in which charges of the other polarity different from the polarity of signal charges are majority carriers is a P-type semiconductor region.

Even if the cathode of an APD is set to a fixed potential and signals are taken out from the anode, the present invention can be implemented. In this case, the semiconductor region of a first conductivity type in which charges of the same polarity as the polarity of signal charges are major carriers is a P-type semiconductor region, and the semiconductor region of a second conductivity type in which charges of the other polarity different from the polarity of signal charges are major carriers is an N-type semiconductor region. The following description will be given of a case where one node of an APD is set to a fixed potential, but potentials of both nodes may be made variable.

In this specification, when a term “impurity concentration” is simply used, the term means a net impurity concentration obtained by subtracting the amount compensated by an impurity of the opposite conductivity type. In short, the “impurity concentration” refers to a NET doping concentration. The region in which the P-type additive impurity concentration is higher than the N-type additive impurity concentration is a P-type semiconductor region. In contrast, the region in which the N-type additive impurity concentration is higher than the P-type additive impurity concentration is an N-type semiconductor region.

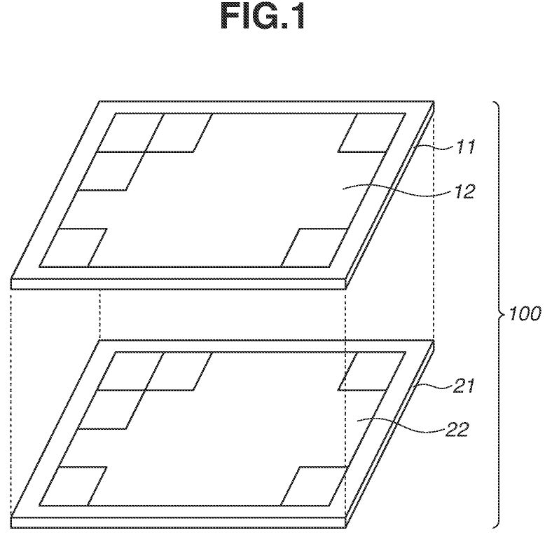

Configurations of a photoelectric conversion apparatus and its driving method that are common to exemplary embodiments of the present invention will be described with reference to FIGS. 1 to 5A, 5B, and 5C.

FIG. 1 is a diagram illustrating a configuration of a stack-type photoelectric conversion apparatus 100 according to one or more exemplary embodiments of the present invention.

The photoelectric conversion apparatus 100 includes two stacked substrates, a sensor substrate 11 and a circuit substrate 21, which are electrically connected to each other. The sensor substrate 11 includes a first semiconductor layer including a photoelectric conversion element 102 to be described below, and a first wiring structure. The circuit substrate 21 includes a second semiconductor layer including a circuit such as a signal processing unit 103 to be described below, and a second wiring structure. The photoelectric conversion apparatus 100 includes the second semiconductor layer, the second wiring structure, the first wiring structure, and the first semiconductor layer, which are stacked in this order. The photoelectric conversion apparatus described in each exemplary embodiment is a back-illuminated photoelectric conversion apparatus that receives light entering from a first surface, and includes a circuit substrate arranged on a second surface.

Hereinafter, the sensor substrate 11 and the circuit substrate 21 will be described as singulated chips, but the sensor substrate 11 and the circuit substrate 21 are not limited to such chips. For example, each substrate may be a wafer. Alternatively, the substrates may be singulated after being stacked in a wafer state, or may be singulated into chips and then jointed by stacking the chips.

A pixel region 12 is arranged on the sensor substrate 11, and a circuit region 22 for processing signals detected in the pixel region 12 is arranged on the circuit substrate 21.

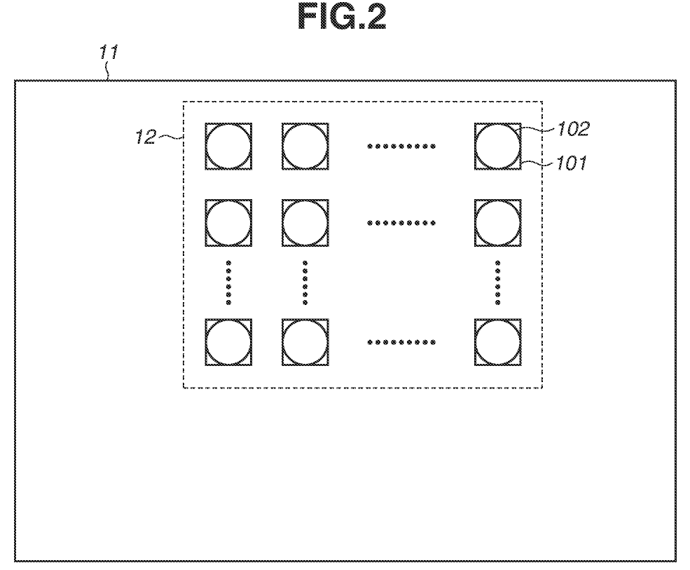

FIG. 2 is a diagram illustrating an arrangement example of the sensor substrate 11. Pixels 101 each including the photoelectric conversion element 102 including an APD are arranged in a two-dimensional array in a planar view, and form the pixel region 12.

Typically, the pixel 101 is a pixel for forming an image. The pixel 101 used in a time of flight (TOF) sensor is not always to form images. In other words, the pixel 101 may be a pixel for measuring the time at which light reaches, and for measuring the quantity of the light.

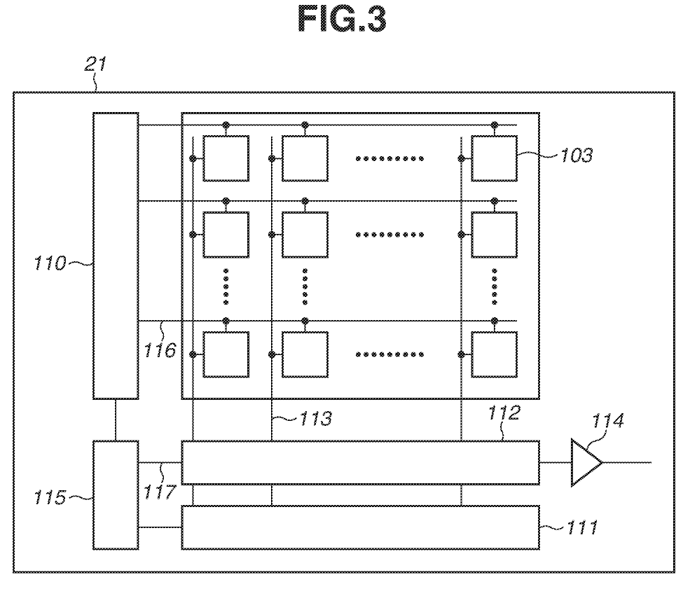

FIG. 3 is a configuration diagram of the circuit substrate 21. The circuit substrate 21 includes the signal processing unit 103 that processes charges photoelectrically-converted by the photoelectric conversion element 102 illustrated in FIG. 2, a readout circuit 112, a control pulse generation unit 115, a horizontal scanning circuit unit 111, a signal line 113, and a vertical scanning circuit unit 110.

The photoelectric conversion element 102 illustrated in FIG. 2 and the signal processing unit 103 illustrated in FIG. 3 are electrically connected via a connection wire provided on each pixel.

The vertical scanning circuit unit 110 receives a control pulse supplied from the control pulse generation unit 115, and supplies the control pulse to each pixel. A logic circuit such as a shift register or an address decoder is used as the vertical scanning circuit unit 110.

A signal output from the photoelectric conversion element 102 of a pixel is processed by the signal processing unit 103. A counter and a memory are provided in the signal processing unit 103, and digital values are stored in the memory.

The horizontal scanning circuit unit 111 inputs to the signal processing unit 103 a control pulse for sequentially selecting each column to read out the signal from the memory of each pixel that stores a digital signal.

A signal is output to the signal line 113 from the signal processing unit 103 of a pixel on a selected column that has been selected by the vertical scanning circuit unit 110.

The signal output to the signal line 113 is output via an output circuit 114 to a recording unit or a signal processing unit outside the photoelectric conversion apparatus 100.

In FIG. 2, photoelectric conversion elements in a pixel region may be one-dimensionally arrayed. Even if the number of pixels is one, the effect of the present invention can be obtained, and such a case is also included in the present invention. Not every photoelectric conversion element may have the function of the signal processing unit. For example, one signal processing unit may be shared by a plurality of photoelectric conversion elements, and signal processing may be sequentially performed.

As illustrated in FIGS. 2 and 3, a plurality of signal processing units 103 is arranged in a region overlapping the pixel region 12 in a planar view. Then, the vertical scanning circuit unit 110, the horizontal scanning circuit unit 111, the readout circuit 112, the output circuit 114, and the control pulse generation unit 115 are arranged overlapping, in a planar view, the region defined by the ends of the sensor substrate 11 and the ends of the pixel region 12. In other words, the sensor substrate 11 includes the pixel region 12, and the non-pixel region arranged around the pixel region 12. Then, the vertical scanning circuit unit 110, the horizontal scanning circuit unit 111, the readout circuit 112, output circuit 114, and the control pulse generation unit 115 are arranged in a region overlapping the non-pixel region in a planar view.

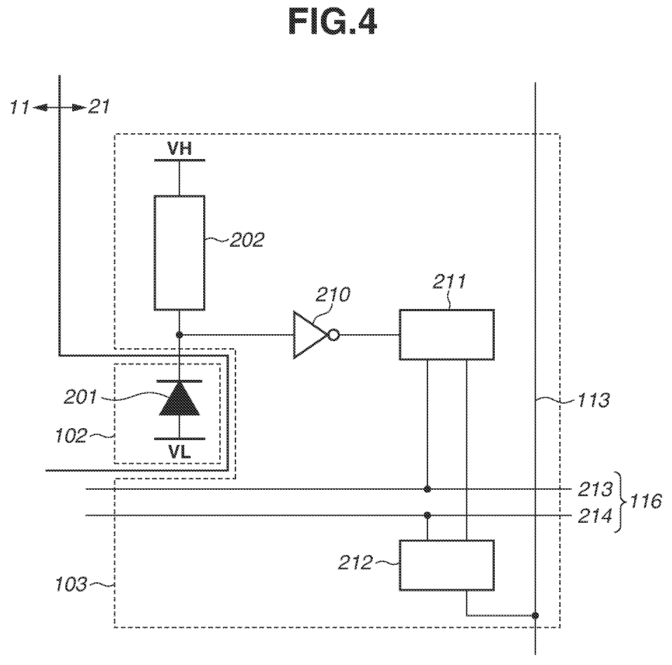

FIG. 4 illustrates an example of a block diagram including an equivalent circuit of FIGS. 2 and 3.

In FIG. 4, the photoelectric conversion element 102 including an APD 201 is provided on the sensor substrate 11, and other members are provided on the circuit substrate 21.

The APD 201 generates a charge pair corresponding to incident light through photoelectric conversion. A voltage VL (first voltage) is supplied to the anode of the APD 201. A voltage VH (second voltage) higher than the voltage VL supplied to the anode is supplied to the cathode of the APD 201. Inversely-biased voltages for causing the APD 201 to bring about avalanche multiplication process are supplied to the anode and the cathode. The state with such voltages supplied brings about avalanche multiplication with charges generated by incident light, which produces an avalanche current.

Inversely-biased voltages are supplied in two mode: a Geiger mode and a linear mode. In the Geiger mode, an APD is operated with a larger potential difference between the anode and the cathode than the breakdown voltage. In the linear mode, an APD is operated with a potential difference between the anode and the cathode close to the breakdown voltage, or with a voltage difference equal to or smaller than the breakdown voltage.

An APD operated in the Geiger mode will be referred to as a single photon avalanche photodiode (SPAD). For example, the voltage VL (first voltage) is -30 V and the voltage VH (second voltage) is 1 V. The APD 201 may be operated in the linear mode, or may be operated in the Geiger mode. Because a potential difference of the SPAD becomes larger and a withstand voltage effect of the SPAD becomes more prominent as compared with the case of an APD in the linear mode, the SPAD is suitably used.

A quench element 202 is connected to the APD 201 and a power source that supplies the voltage VH. The quench element 202 functions as a load circuit (quench circuit) when a signal is multiplied by avalanche multiplication, and has a function of suppressing avalanche multiplication by reducing a voltage to be supplied to the APD 201 (quenching). The quench element 202 also has a function of returning a voltage to be supplied to the APD 201, to the voltage VH by running a current by the amount corresponding to a voltage drop caused by the quenching (recharging).

The signal processing unit 103 includes a waveform shaping unit 210, a counter circuit 211, and a selection circuit 212. In this specification, the signal processing unit 103 includes at least one of the waveform shaping unit 210, the counter circuit 211, or the selection circuit 212.

The waveform shaping unit 210 outputs a pulse signal by shaping a potential change of the cathode of the APD 201 that is obtained at the time of photon detection. For example, an inverter circuit is used as the waveform shaping unit 210. FIG. 4 illustrates an example in which one inverter is used as the waveform shaping unit 210, but a circuit in which a plurality of inverters is connected in series may be used, or another circuit having a waveform shaping effect may be used.

The counter circuit 211 counts the number of pulse signals output from the waveform shaping unit 210, and stores the count value. When a control pulse pRES is supplied via a drive line 213, the number of pulse signals that is stored in the counter circuit 211 is reset.

The control pulse pSEL is supplied to the selection circuit 212 from the vertical scanning circuit unit 110 illustrated in FIG. 3, via a drive line 214 illustrated in FIG. 4 (not illustrated in FIG. 3), and electric connection and separation between the counter circuit 211 and the signal line 113 are switched. The selection circuit 212 includes a buffer circuit for outputting a signal, for example.

Electric connection may be switched by a switch such as a transistor disposed between the quench element 202 and the APD 201, or between the photoelectric conversion element 102 and the signal processing unit 103. Similarly, the supply of the voltage VH or the voltage VL to the photoelectric conversion element 102 may be electrically switched using a switch such as a transistor.

In the present exemplary embodiment, the configuration that uses the counter circuit 211 has been described. On the other hand, the photoelectric conversion apparatus 100 may acquire a pulse detection timing using a time to digital converter (hereinafter, TDC) and a memory in place of the counter circuit 211. In this case, the generation timing of a pulse signal output from the waveform shaping unit 210 is converted into a digital signal by the TDC. To measure the timing of a pulse signal, a control pulse pREF (reference signal) is supplied via a drive line to the TDC from the vertical scanning circuit unit 110 illustrated in FIG. 1. Based on the control pulse pREF, the TDC acquires a digital signal indicating an input timing of a signal output from each pixel via the waveform shaping unit 210, as a relative time.

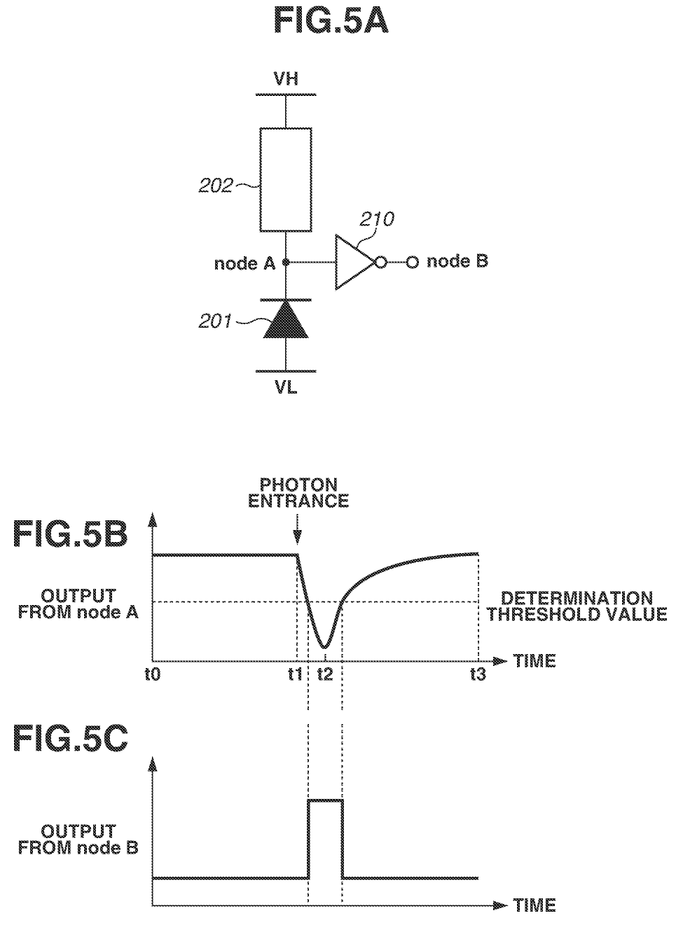

FIGS. 5A to 5C are diagrams schematically illustrating a relationship between an operation of an APD and an output signal.

FIG. 5A is a diagram extracting the APD 201, the quench element 202, and the waveform shaping unit 210, all of which are illustrated in FIG. 4. In FIG. 5A, a node A is on the input side and a node B is on the output side of the waveform shaping unit 210. FIG. 5B illustrates a waveform change at the node A in FIGS. 5A, and 5C illustrates a waveform change at the node B in FIG. 5A.

During the period from a time to to a time t1, the potential difference VH-VL is applied to the APD 201 in FIG. 5A. If a photon enters the APD 201 at the time t1, avalanche multiplication occurs in the APD 201, an avalanche multiplication current runs to the quench element 202, and the voltage at the node A drops. If the amount of voltage drop further increases, and the potential difference applied to the APD 201 becomes smaller, avalanche multiplication in the APD 201 stops at a time t2, and the voltage level at the node A stops dropping from a certain fixed value. After that, during the period from the time t2 to a time t3, a current compensating for the voltage drop from the voltage VL runs to the node A, and the potential level at the node A is statically settled at the original potential level at the time t3. At this time, the portion of the output waveform exceeding a certain threshold value at the node A is subjected to waveform shaping performed by the waveform shaping unit 210, and output as a signal at the node B.

The arrangement of the signal lines 113, and the arrangement of the readout circuit 112 and the output circuit 114 are not limited to those illustrated in FIG. 3. For example, the signal lines 113 may be arranged extending in the row direction, and the readout circuit 112 may be arranged at the ends of the extending signal lines 113.

Hereinafter, a photoelectric conversion apparatus of each exemplary embodiment will be described.

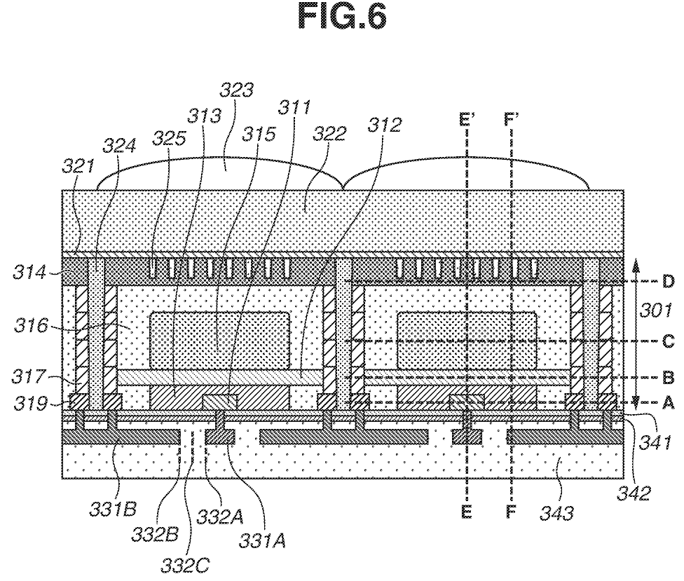

A photoelectric conversion apparatus according to a first exemplary embodiment will be described with reference to FIGS. 6 to 10A and 10B.

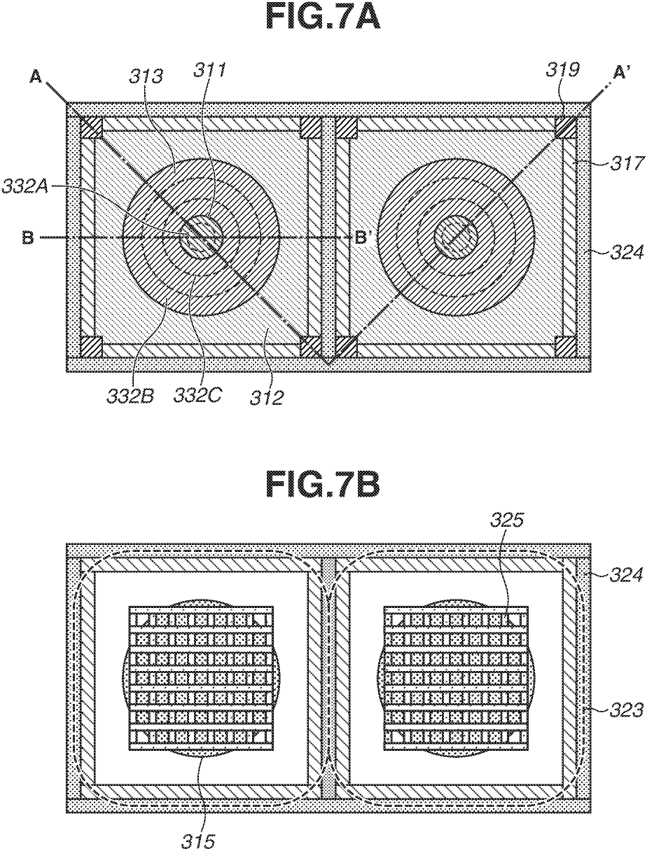

FIG. 6 is a cross-sectional view illustrating the photoelectric conversion elements 102 of the photoelectric conversion apparatus according to the first exemplary embodiment that correspond to two pixels, in the direction vertical to the surface direction of the substrate, and corresponds to an A-A' cross section in FIG. 7A.

The structure and the function of the photoelectric conversion element 102 will be described. The photoelectric conversion element 102 includes an N-type first semiconductor region 311, an N-type third semiconductor region 313, an N-type fifth semiconductor region 315, and an N-type sixth semiconductor region 316. The photoelectric conversion element 102 further includes a P-type second semiconductor region 312, a P-type fourth semiconductor region 314, a P-type seventh semiconductor region 317, and a P-type ninth semiconductor region 319.

In the present exemplary embodiment, in the cross section illustrated in FIG. 6, the N-type first semiconductor region 311 is formed near the surface facing the light incidence surface, and the N-type third semiconductor region 313 is formed around the first semiconductor region 311. The P-type second semiconductor region 312 is formed at a position overlapping the first semiconductor region 311 and the third semiconductor region 313 in a planar view. The N-type fifth semiconductor region 315 is further arranged at a position overlapping the second semiconductor region 312 in a planar view, and the N-type sixth semiconductor region 316 is formed around the fifth semiconductor region 315.

The N-type impurity concentration of the first semiconductor region 311 is higher than those of the third semiconductor region 313 and the fifth semiconductor region 315. A PN junction is formed between the P-type second semiconductor region 312 and the N-type first semiconductor region 311. The impurity concentration of the second semiconductor region 312 here is lower than that of the first semiconductor region 311, so that the region of the second semiconductor region 312 that overlaps the center of the first semiconductor region 311 in a planar view entirely becomes a depletion layer region. At this time, the potential difference between the first semiconductor region 311 and the second semiconductor region 312 is larger than the potential difference between the second semiconductor region 312 and the fifth semiconductor region 315. Furthermore, the depletion layer region is extended up to a partial region of the first semiconductor region 311, and a strong electric field is induced in the extended depletion layer region. The strong electric field causes avalanche multiplication to occur in the depletion layer region extended up to the partial region of the first semiconductor region 311, and a current based on the amplified charges is output as signal charges. When light that has entered the photoelectric conversion element 102 is photoelectrically-converted, and the avalanche multiplication occurs in the depletion layer region (avalanche multiplication region), generated charges of the first conductivity type are collected into the first semiconductor region 311.

In FIG. 6, the third semiconductor region 313 and the fifth semiconductor region 315 are formed in a nearly equal size, but the sizes of the third semiconductor region 313 and the fifth semiconductor region 315 are not limited to this size. For example, the fifth semiconductor region 315 may be formed in a size larger than that of the third semiconductor region 313, and charges may be collected into the first semiconductor region 311 from a broader range of the semiconductor region.

The third semiconductor region 313 may be a P-type semiconductor region instead of an N-type semiconductor region. In this case, the impurity concentration of the third semiconductor region 313 is set to a lower impurity concentration than the impurity concentration of the second semiconductor region 312. This is because, if the impurity concentration of the third semiconductor region 313 is too high, an avalanche multiplication region is formed between the third semiconductor region 313 and the first semiconductor region 311, and the dark count rate (DCR) increases.

A recess and protrusion structure 325 in a trench structure is formed in the surface on the light incidence surface side of the semiconductor layer. The recess and protrusion structure 325 is surrounded by the P-type fourth semiconductor region 314, and scatters light that has entered the photoelectric conversion element 102. Because incident light travels at a slant in the photoelectric conversion element 102, the optical path length can be equal to or larger than the thickness of a semiconductor layer 301, and light with a longer wavelength can be photoelectrically-converted as compared with a case where the recess and protrusion structure 325 is not provided. Because the reflection of incident light in the substrate is prevented by the recess and protrusion structure 325, the effect of improvement in photoelectric conversion efficiency of incident light can be obtained. Furthermore, with the recess and protrusion structure 325 combined with an anode wire having an extended shape, which is a characteristic part of the present invention, the anode wire efficiently reflects light diffracted by the recess and protrusion structure 325 in an oblique direction, which can further increase near-infrared light sensitivity.

The fifth semiconductor region 315 and the recess and protrusion structure 325 are formed overlapping each other in a planar view. The area of the portion in which the fifth semiconductor region 315 and the recess and protrusion structure 325 overlap each other in a planar view is larger than the area of the portion of the fifth semiconductor region 315 that does not overlap the recess and protrusion structure 325. For charges generated at positions distant from the avalanche multiplication region formed between the first semiconductor region 311 and the fifth semiconductor region 315, the traveling time taken to reach the avalanche multiplication region becomes longer than the time taken for charges generated at positions close to the avalanche multiplication region to reach the avalanche multiplication region. Thus, timing jitter might increase. The arrangement of the fifth semiconductor region 315 and the recess and protrusion structure 325 at positions overlapping each other in a planar view can strengthen the electric field of the photodiode deep portion, which leads to a shorter time to collect charges generated at positions distant from the avalanche multiplication region, whereby can reduce timing jitter.

In addition, the fourth semiconductor region 314 three-dimensionally covers the recess and protrusion structure 325, reducing the generation of thermally-excited charges at the interface portions of the recess and protrusion structure 325. This reduces the DCR of the photoelectric conversion element 102.

Pixels are isolated by a pixel isolation portion 324 having a trench structure, and the P-type seventh semiconductor region 317 formed around the pixel isolation portion 324 isolates neighboring photoelectric conversion elements 102 by a potential barrier. Because the photoelectric conversion elements 102 are isolated also by a potential of the seventh semiconductor region 317, a pixel isolation portion having a trench structure such as the pixel isolation portion 324 is not always used, and the depth and the position of the pixel isolation portion 324 having a trench structure are not limited to those illustrated in FIG. 6. The pixel isolation portion 324 may be a deep trench isolation (DTI) penetrating through a semiconductor layer, or may be a DTI not penetrating through a semiconductor layer. Metal may be buried into the DTI to improve the light blocking effect. The pixel isolation portion 324 may be formed of a silicon monoxide (SiO), a fixed charge film, a metal member, polysilicon (Poly-Si), or a combination of these. The pixel isolation portion 324 may be formed surrounding the entire perimeter of the photoelectric conversion element 102 in a planar view, or may be formed in a portion facing the side of the photoelectric conversion element 102, for example. A voltage may be applied to a buried member to induce charges on a trench interface to reduce the DCR.

The distance from the pixel isolation portion 324 to a neighboring pixel or a pixel provided at the proximate position to the pixel isolation portion 324 can be regarded as the size of one photoelectric conversion element 102. Let L denote the size of one photoelectric conversion element 102, a distance d from the light incidence surface to an avalanche multiplication region satisfies L√2/4 < d < L×√2. When the size and the depth of the photoelectric conversion element 102 satisfy this relation, the strength of the electric field in the depth direction and the strength of the electric field in the planar direction in the vicinity of the first semiconductor region 311 are nearly equal. This can reduce the variation in time taken for charge collection, reducing timing jitter.

A pinning film 321, a planarization film 322, and a microlens 323 are further formed on the light incidence surface side of the semiconductor layer. A filter layer (not illustrated) may be further arranged on the light incidence surface side. Various optical filters such as a color filter, an infrared light cut filter, and a monochrome filter can be used as a filter layer. An RGB color filter or an RGBW color filter can be used as a color filter.

A wiring structure including a conductor and an insulating film is provided on the surface of a semiconductor layer that faces the light incidence surface. The photoelectric conversion element 102 illustrated in FIG. 6 includes an oxidized film 341 and a protective film 342 in this order at positions closer to the semiconductor layer, and wiring layers including conductors are further stacked. An interlayer film 343 as an insulating film is provided between wires and the semiconductor layer and between the wiring layers. The protective film 342 is a film for protecting an avalanche diode from plasma damage and metal pollution that might be caused in etching.

Silicon nitride (SiN) used as a nitride film is generally used, but silicon oxynitride (SiON), silicon carbide (SiC), or silicon carbonitride (SiCN) may be used.

A cathode wire 331A is connected to the first semiconductor region 311, and an anode wire 331B supplies a voltage to the seventh semiconductor region 317 via the ninth semiconductor region 319 as an anode contact. In the present exemplary embodiment, the cathode wire 331A and the anode wire 331B are formed in the same wiring layer. Wires are formed of conductors including metal such as copper (Cu) and aluminum (Al), for example. In this cross section, a cathode wire outer circumferential portion 332A indicates the outer circumferential portion of the cathode wire 331A, and an anode wire inner circumferential portion 332B indicates the inner circumferential portion of the anode wire 331B that faces the cathode wire outer circumferential portion 332A. A virtual line 332C indicated by a dotted line divides the distance between the cathode wire outer circumferential portion 332A and the anode wire inner circumferential portion 332B into equal distances internally.

FIGS. 7A and 7B are pixel plan views each illustrating two pixels of the photoelectric conversion apparatus according to the first exemplary embodiment. FIG. 7A is a plan view illustrating two pixels in sight of the surface facing the light incidence surface in a planar view. FIG. 7B is a plan view illustrating two pixels in sight of the light incidence surface side in a planar view.

The first semiconductor region 311, the third semiconductor region 313, and the fifth semiconductor region 315 have a circular shape, and are arranged in a concentric pattern. In FIG. 7A illustrates the arrangement of the first semiconductor region 311 and the third semiconductor region 313. In FIG. 7B illustrates the arrangement of the fifth semiconductor region 315. This structure reduces the electric field locally concentrating on the end of the strong electric field region between the first semiconductor region 311 and the second semiconductor region 312, reducing the DCR. The shape of each semiconductor region is not limited to a circular shape. For example, the semiconductor regions may be shaped in polygons of which the centroid positions are aligned with one another.

The dotted lines on the first semiconductor region 311 and the third semiconductor region 313 indicate ranges of the cathode wire 331A and the anode wire 331B respectively provided in a planar view. The cathode wire 331A has a circular shape in a planar view, and the outer circumferential portion 332A of the cathode wire 331A overlaps the first semiconductor region 311 in a planar view. The inner circumferential portion 332B of the anode wire 331B is a surface having a circular hole, and entirely overlaps the third semiconductor region 313 in a planar view. In other words, the boundary between the anode wire 331B and the insulating film that faces the cathode wire 331A overlaps the third semiconductor region 313. The virtual line 332C equally dividing the distance between the cathode wire outer circumferential portion 332A and the anode wire inner circumferential portion 332B overlaps the third semiconductor region 313 and does not overlap the first semiconductor region 311.

An avalanche multiplication region is formed between the first semiconductor region 311 and the second semiconductor region 312 in the depth direction, and an electric field mitigation region is provided surrounding this avalanche multiplication region. The electric field mitigation region may not cover the perimeter of the avalanche multiplication region, and may partly cover the perimeter of the avalanche multiplication region. The boundary between the anode wire 331B and the insulating film that faces the cathode wire 331A overlaps this electric field mitigation region in a planar view. Alternatively, the virtual line 332C equally dividing the distance between the cathode wire outer circumferential portion 332A and the anode wire inner circumferential portion 332B can overlap the electric field mitigation region.

The ninth semiconductor region 319 is seen in a cross section taken along an A-A′ direction (diagonal directions of the pixel) in FIG. 7A, and is not seen in a cross section taken along a B-B' direction (the opposite side direction of the pixel). In the cross section taken along the B-B' direction, instead of the absence of the ninth semiconductor region 319, the seventh semiconductor region 317 extends up to the surface facing the light incidence surface side.

In FIG. 7B, the recess and protrusion structure 325 is formed like a grid in a planar view. The recess and protrusion structure 325 is formed overlapping the first semiconductor region 311 and the fifth semiconductor region 315, and the centroid position of the recess and protrusion structure 325 falls within the avalanche multiplication region in a planar view. In a grid-like trench structure as illustrated in FIG. 7B, the trench depth at an intersection point of trenches is deeper than the trench depth in the portion in which a trench extends alone. On the other hand, the bottom of the trench at an intersection point of trenches exists at a position closer to the light incidence surface than the half position of the thickness of the semiconductor layer. The trench depth refers to the depth from the second surface to the bottom, and can also be said to be the depth of a recess of the recess and protrusion structure 325.

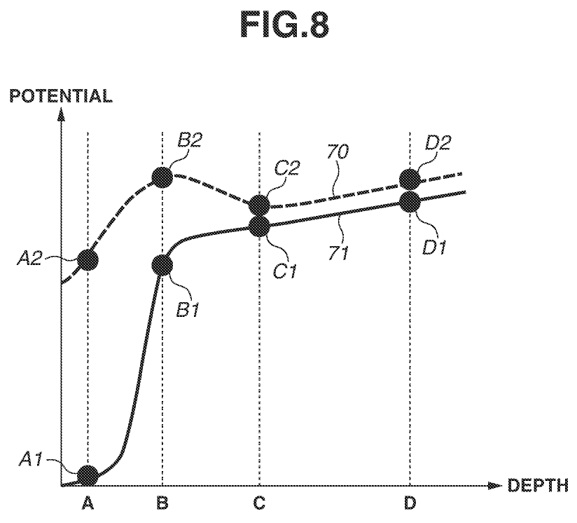

FIG. 8 is potential diagram of the photoelectric conversion element 102 illustrated in FIG. 6.

A dotted line 70 in FIG. 8 indicates a potential distribution of a line FF' in FIG. 6, and a solid line 71 in FIG. 8 indicates a potential distribution of a line EE' in FIG. 6. FIG. 8 illustrates a potential with reference to electrons as main carrier charges of an N-type semiconductor region. If main carrier charges are holes, the relationship between levels of potentials is reversed. A depth A in FIG. 8 corresponds to a height A in FIG. 6. Similarly, depths B, C, and D respectively correspond to heights B, C, and D.

In FIG. 8, the potential height indicated by the solid line 71 at the depth A is denoted by A1, the potential height indicated by the dotted line 70 at the depth A is denoted by A2, the potential height indicated by the solid line 71 at the depth B is denoted by B 1, and the potential height indicated by the dotted line 70 at the depth B is denoted by B2. In addition, the potential height indicated by the solid line 71 at the depth C is denoted by C1, the potential height indicated by the dotted line 70 at the depth C is denoted by C2, the potential height indicated by the solid line 71 at the depth D is denoted by D1, and the potential height indicated by the dotted line 70 at the depth D is denoted by D2.

As seen from FIGS. 6 and 8, the potential height of the first semiconductor region 311 corresponds to the potential height A1, and the potential height of a point near the central part of the second semiconductor region 312 corresponds to the potential height B1. In addition, the potential height of the fifth semiconductor region 315 corresponds to the potential height A2, and the potential height of the outer edge part of the second semiconductor region 312 corresponds to the potential height B2.

With regard to the dotted line 70 in FIG. 8, the potential gradually decreases from the depth D toward the depth C. Then, the potential gradually increases from the depth C toward the depth B, and reaches the potential height B2 at the depth B. Furthermore, the potential decreases from the depth B toward the depth A, and reaches the potential height A2 at the depth A.

On the other hand, with regard to the solid line 71, the potential gradually decreases from the depth D toward the depth C and from the depth C toward the depth B, and reaches the potential height B 1 at the depth B. Then, the potential steeply decreases from the depth B toward the depth A, and reaches the potential height A1 at the depth A. At the depth D, the potentials indicated by the dotted line 70 and the solid line 71 are at almost the same height, and the region indicated by the line EE' and the line FF' has a potential gradient of gradually decreasing toward the second surface of the semiconductor layer 301. Thus, charges generated in a light detection apparatus move toward the second surface along the gradual potential gradient.

In an avalanche diode of the present exemplary embodiment, the impurity concentration of the P-type second semiconductor region 312 is lower than that of the N-type first semiconductor region 311, and inversely-biased potentials are supplied to the first semiconductor region 311 and the second semiconductor region 312. This configuration forms a depletion layer region in the second semiconductor region 312. In such a structure, the second semiconductor region 312 functions as a potential barrier for charges photoelectrically-converted in the fourth semiconductor region 314, which facilitates collection of the charges into the first semiconductor region 311.

In FIG. 6, the second semiconductor region 312 is formed over the entire surface of the photoelectric conversion element 102, but the portion overlapping the first semiconductor region 311 in a planar view, for example, may be an N-type semiconductor region without the second semiconductor region 312 as a P-type semiconductor region. The impurity concentration of this N-type semiconductor region is set to an impurity concentration lower than the impurity concentration of the first semiconductor region 311. If an N-type semiconductor layer is used, the second semiconductor region 312 is not provided at a portion overlapping the first semiconductor region 311 in a planar view. In this case, it can be understood that the fourth semiconductor region 314 having a slit portion is formed. In this case, the potential difference between the second semiconductor region 312 and the slit portion, at the depth C in FIG. 6 causes potential decreases in the direction from the line FF' toward the line EE'. This configuration facilitates the movement of photoelectrically-converted charges in the fourth semiconductor region 314 in the direction of the first semiconductor region 311. On the other hand, a configuration with the second semiconductor region 312 formed over the entire surface as illustrated in FIG. 6 allows the application of a lower voltage for the generation of a strong electric field for avalanche multiplication, reducing noise caused by the formation of a locally strong electric field region.

The charges that have moved to the vicinity of the second semiconductor region 312 are subjected to avalanche multiplication through acceleration along a steep potential gradient from the depth B toward the depth A indicated by the solid line 71 in FIG. 8 (i.e., strong electric field).

In contrast to this, avalanche multiplication does not occur in the potential distribution of the region between the fifth semiconductor region 315 and the P-type second semiconductor region 312 in FIG. 6 (i.e., the region from the depth B toward the depth A indicated by the dotted line 70 in FIG. 8). Thus, charges generated in the fourth semiconductor region 314 can be counted as signal charges without increasing the area of a strong electric field region (avalanche multiplication region) with respect to the size of a photodiode. The description has been given so far assuming that the conductivity type of the fifth semiconductor region 315 is an N type, but the fifth semiconductor region 315 may be a P-type semiconductor region as long as densities satisfy the above-described potential relationship.

The charges photoelectrically-converted in the second semiconductor region 312 flow into the fourth semiconductor region 314 along the potential gradient from the depth B toward the depth C indicated by the dotted line 70 in FIG. 8. The configuration facilitates the movement of the charges in the fourth semiconductor region 314 to the second semiconductor region 312 for the above-described reason. Thus, charges photoelectrically-converted in the second semiconductor region 312 move to the first semiconductor region 311, and are detected as signal charges by avalanche multiplication. Thus, the photoelectric conversion element 102 has sensitivity to charges photoelectrically-converted in the second semiconductor region 312.

The dotted line 70 in FIG. 8 also indicates a cross-sectional potential along the line FF' in FIG. 3. On the dotted line 70, the point at which the height A and the line FF' in FIG. 6 intersect with each other is denoted by A2, the point at which the height B and the line FF' intersect with each other is denoted by B2, the point at which the height C and the line FF' intersect with each other is denoted by C2, and the point at which the height D and the line FF' intersect with each other is denoted by D2. Electrons photoelectrically-converted in the fourth semiconductor region 314 in FIG. 6 move along the potential gradient from the potential height D2 toward the potential height C2 in FIG. 8, but the electrons cannot get across the region from the potential height C2 to the potential height B2 because the region functions as a potential barrier for the electrons. The electrons therefore move to the vicinity of the central part of the fourth semiconductor region 314 in FIG. 6 indicated by the line EE'. The arrived electrons move along the potential gradient from the potential height C1 toward the potential height B1 in FIG. 8, and are subjected to avalanche multiplication along the steep potential gradient from the potential height B1 toward the potential height A1, passes through the first semiconductor region 311, and are detected as signal charges.

Charges generated near the boundary between the third semiconductor region 313 and the sixth semiconductor region 316 in FIG. 6 move along the potential gradient from the potential height B2 toward the potential height C2 in FIG. 8. After that, as described above, the charges move to the vicinity of the central part of the fourth semiconductor region 314 in FIG. 6 indicated by the line EE'. Then, the charges are subjected to avalanche multiplication along the steep potential gradient from the potential height B1 toward the potential height A1. The charges through avalanche multiplication passes through the first semiconductor region 311, and are detected as signal charges.

The strong electric field around the first semiconductor region 311 results in imbalance of thermal states between the sensor substrate and the carriers, producing hot carriers. The hot carriers are trapped into a trap site in the periphery of the cathode region close to the wiring layer. The hot carriers to be trapped increase with time, and the potential of the vicinity of the cathode region and the electric field strength in the strong electric field region also change with time, which leads to a concern about change in breakdown voltage with time.

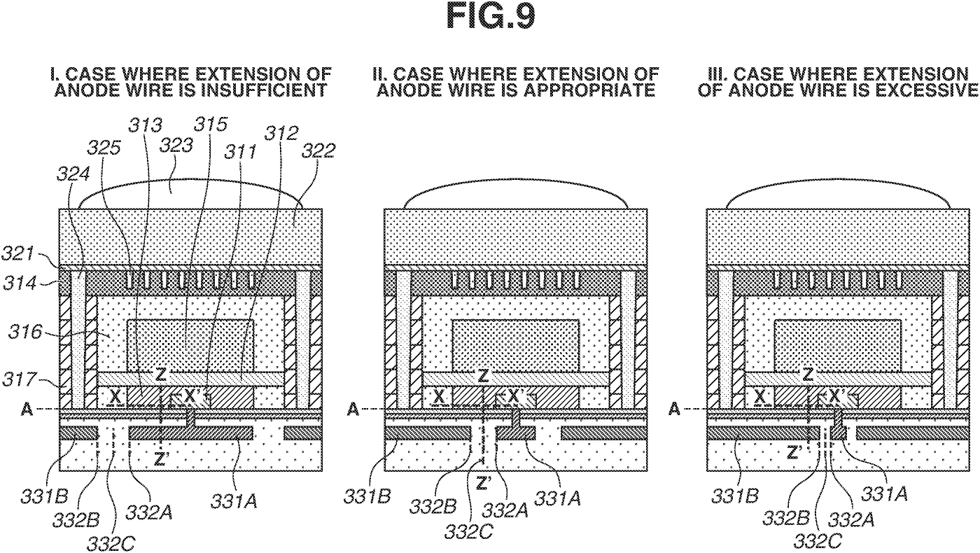

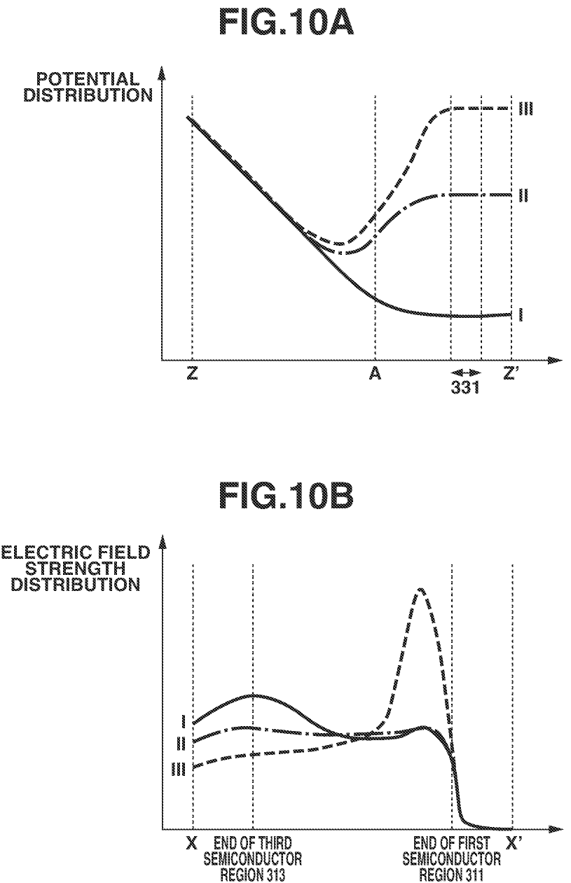

The concern and effect of the present exemplary embodiment will be described with reference to FIG. 9 illustrating cross-sectional comparison diagrams of the photoelectric conversion element 102, and FIGS. 10A and 10B respectively illustrating a potential distribution and an electric field strength distribution in the vicinity of the wiring layer in each cross-sectional comparison diagram in FIG. 9. The cross sections illustrated in FIG. 9 correspond to the B-B' cross section in FIG. 7A, and (I) of FIG. 9 illustrates a case where the extension of the anode wire 331B is insufficient, (II) of FIG. 9 illustrates a case where the extension of the anode wire 331B is appropriate, and (III) of FIG. 9 illustrates a case where the extension of the anode wire 331B is excessive.

In a case where the virtual line 332C equally dividing the distance between the cathode wire outer circumferential portion 332A and the anode wire inner circumferential portion 332B does not overlap the third semiconductor region 313 as illustrated in (I) of FIG. 9, the extension of the anode wire 331B is insufficient, which has no effect of reducing the temporal change in breakdown voltage. On the other hand, in a case where the anode wire 331B extends to such an extent that the virtual line 332C overlaps the first semiconductor region 311 as illustrated in (III) of FIG. 9, the extension is excessive, which causes the electric field to concentrate on the end of the first semiconductor region 311, increasing the DCR. (II) of FIG. 9 illustrates a configuration including the anode wire 331B appropriately-extended in such a manner that the virtual line 332C overlaps the third semiconductor region 313 and does not overlap the first semiconductor region 311.

FIG. 10A is a schematic diagram illustrating a potential distribution in a Z-Z' cross section in each cross-sectional view illustrated in FIG. 9, and FIG. 10B is a schematic diagram illustrating an electric field strength distribution in an X-X' cross section in each cross-sectional view illustrated in FIG. 9.

To reduce the temporal change in breakdown voltage, it is suitable that the potential at the height A is higher than the potential in the region from the height A to the height Z in the Z-Z' cross section in the third semiconductor region 313. In other words, it is suitable that a potential barrier is formed at the height A between heights Z and Z'. As indicated by lines I to III in FIG. 10A, as the end of the anode wire 331B gets closer to the pixel center (i.e., the vicinity of the Z-Z' cross section), such potential arrangement becomes more likely to be satisfied.

On the other hand, as indicated by a line III in FIG. 10B, if the anode wire 331B extends to such an extent that the end of the anode wire 331B overlaps the first semiconductor region 311 in a planar view, the electric field is induced to concentrate on the end of the first semiconductor region 311. The electric field concentration on the end of the first semiconductor region 311 causes increased dark current, which increases the DCR. For this reason, it is suitable to design the anode wire 331B with its appropriate extension length as illustrated in (II) of FIG. 9.

Such an extension of an anode wire allows reduction of the temporal change in breakdown voltage while reducing the DCR. To further enhance the reduction effect of the temporal change in breakdown voltage, it is suitable to shorten the distance in the depth direction between the semiconductor layer and the anode wire 331B. Specifically, among a plurality of wiring layers, the anode wire 331B is provided in a wiring layer that exists as close as possible to the semiconductor layer. Desirably, the anode wire 331B is provided in a wiring layer closest to the semiconductor layer among a plurality of wiring layers. The plurality of wiring layers are wiring layers provided above the top surface of the contact plug connecting the cathode wire 331A and the first semiconductor region 311. In other words, the distance between the second surface and a wiring layer including a plurality of wiring layers in the direction vertical to the in-plane direction of the second surface of the semiconductor layer is larger than the distance between the second surface of the semiconductor layer and the portion of a contact plug that is farthest from the second surface (contact plug top surface).

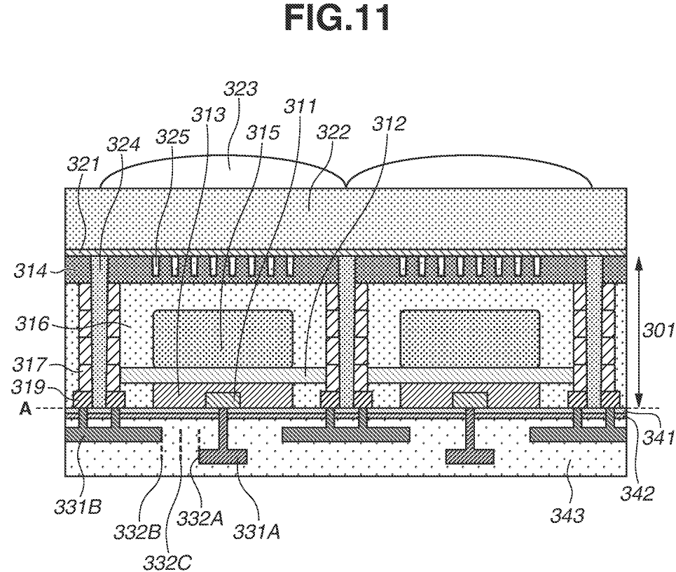

A photoelectric conversion apparatus according to a second exemplary embodiment will be described with reference to FIG. 11.

The descriptions common to those in the first exemplary embodiment will be omitted, and the difference from the first exemplary embodiment will be mainly described. In the present exemplary embodiment, a cathode wire 331A and an anode wire 331B are formed at different heights with respect to the semiconductor layer.

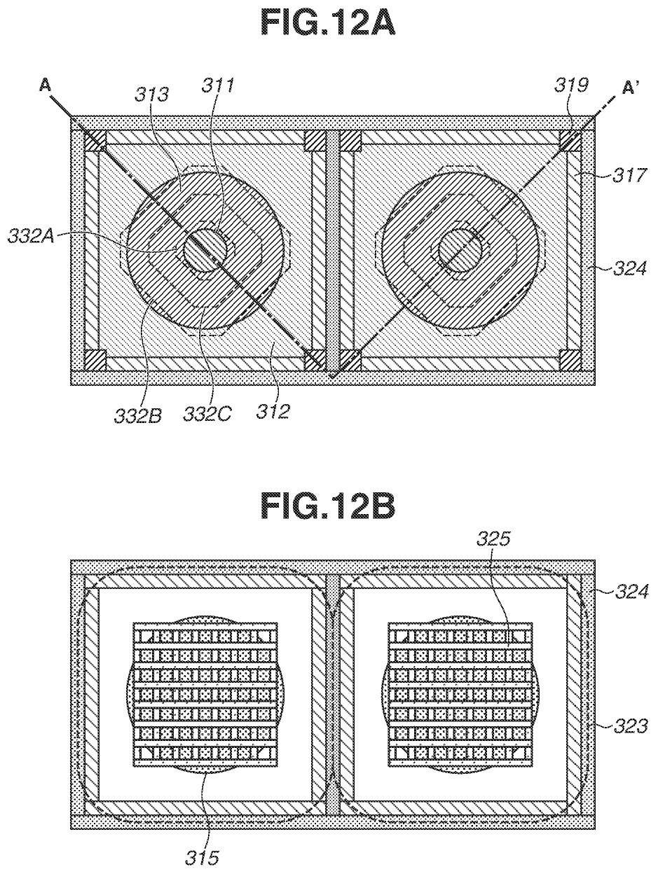

FIG. 11 is a cross-sectional view illustrating the photoelectric conversion elements 102 of the photoelectric conversion apparatus according to the second exemplary embodiment that correspond to two pixels, in the direction vertical to the surface direction of a substrate, and corresponds to an A-A' cross section in FIG. 12A.

In the first exemplary embodiment, the cathode wire 331A and the anode wire 331B are formed in the same wiring layer. In the present exemplary embodiment, the cathode wire 331A and the anode wire 331B are formed at different positions in the depth direction with respect to the semiconductor layer. This configuration provides a sufficient distance between the cathode wire 331A and the anode wire 331B, enhancing the latitude of wiring layout.

FIGS. 12A and 12B are pixel plan views each illustrating two pixels of the photoelectric conversion apparatus according to the second exemplary embodiment. FIG. 12A is a plan view illustrating two pixels in sight of the surface facing the light incidence surface in a planar view. FIG. 12B is a plan view illustrating two pixels in sight of the light incidence surface side in a planar view.

The dotted lines on the first semiconductor region 311 and the third semiconductor region 313 indicates ranges of the cathode wire 331A and the anode wire 331B respectively provided in a planar view. The cathode wire 331A is a polygon in a planar view, and the inner circumferential portion of the anode wire 331B is a surface having a polygonal hole. In FIG. 12B, the planar shape of the cathode wire 331A and the inner circumferential portion of the hole included in the anode wire 331B are similar figures, but the shapes of the cathode wire 331A and the anode wire 331B are not limited to these. In the present exemplary embodiment, the outer circumferential portion 332A of the cathode wire 331A entirely overlaps the third semiconductor region 313 in a planar view, but a part or all of the outer circumferential portion 332A may overlap the first semiconductor region 311, for example. In addition, the inner circumferential portion 332B of the anode wire 331B partially overlaps the third semiconductor region 313 in a planar view, but the shape and the arrangement of the inner circumferential portion 332B are not limited to these as long as the virtual line 332C is located entirely overlapping the third semiconductor region 313 in a planar view.

### Modified Example of Second Exemplary Embodiment

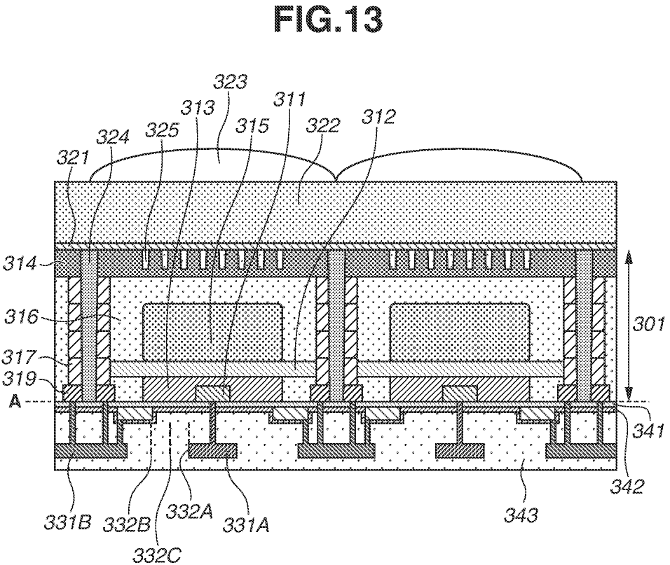

A modified example of the second exemplary embodiment will be described with reference to FIG. 13.

In this modified example, a Poly-Si wire is formed as the anode wire 331B. This modified example is similar to the first and second exemplary embodiments in that the virtual line 332C equally dividing the distance between the cathode wire outer circumferential portion 332A and the anode wire inner circumferential portion 332B overlaps the third semiconductor region 313 and does not overlap the first semiconductor region 311.

The Poly-Si wire formed as the anode wire 331B makes the distance in the depth direction between the semiconductor layer and the anode wire 331B smaller, further reducing the temporal change in breakdown voltage.

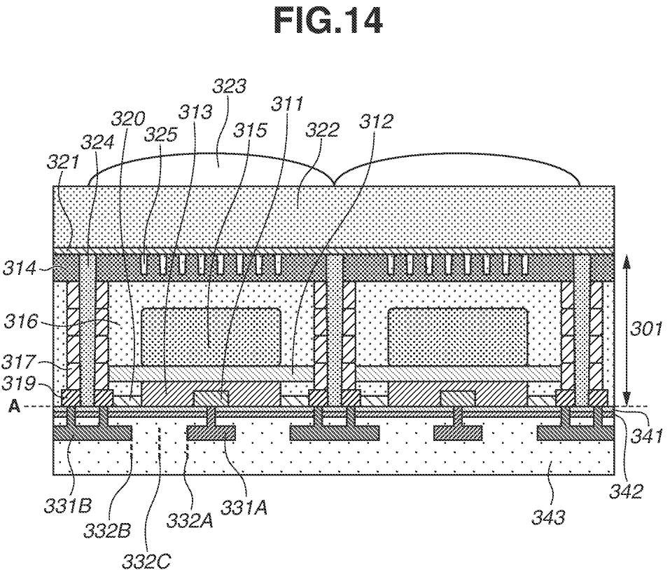

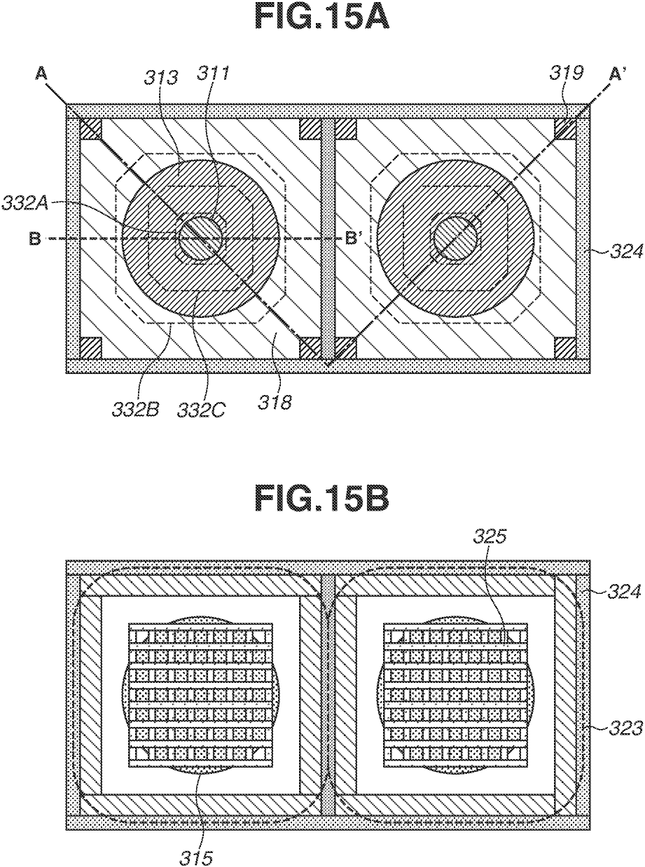

A photoelectric conversion apparatus according to a third exemplary embodiment will be described with reference to FIGS. 14, 15A, and 15B.

The descriptions common to those in the first and second exemplary embodiments will be omitted, and the difference from the first exemplary embodiment will be mainly described. In the present exemplary embodiment, the description will be given of a configuration that has an effect of reducing the temporal change in breakdown voltage even without the end of the anode wire 331B and the third semiconductor region 313 overlapping each other in a planar view.

FIG. 14 is a cross-sectional view illustrating the photoelectric conversion elements 102 of the photoelectric conversion apparatus according to the third exemplary embodiment that correspond to two pixels, in the direction vertical to the surface direction of a substrate, and corresponds to an A-A' cross section in FIG. 15A. The photoelectric conversion element 102 includes a tenth semiconductor region 320 between the third semiconductor region 313 and the ninth semiconductor region 319, and the inner circumferential portion 332B of the anode wire 331B overlaps the tenth semiconductor region 320 in a planar view.

As described in the first exemplary embodiment, the potential at the height A point of the third semiconductor region 313 is affected by the potential of the anode wire 331B. Approximately, it is considered that the influence of the potential of the anode wire 331B reaches a Si interface portion up to the virtual line 332C existing at the equal distance from the cathode wire 331A and the anode wire 331B. Thus, even if the anode wire 331B and the third semiconductor region 313 do not overlap each other in a planar view, at least part of the virtual line 332C and the third semiconductor region 313 overlap each other in a planar view allows reduction of the temporal change in breakdown voltage.

FIGS. 15A and 15B are pixel plan views each illustrating two pixels of the photoelectric conversion apparatus according to the third exemplary embodiment. FIG. 15A is a plan view illustrating two pixels in sight of the surface facing the light incidence surface in a planar view. FIG. 15B is a plan view illustrating two pixels in sight of the light incidence surface side in a planar view.

In FIG. 15A, the inner circumferential portion 332B of the anode wire 331B does not overlap the third semiconductor region 313 in a planar view, and the virtual line 332C entirely overlaps the third semiconductor region 313 in a planar view.

In the pixels according to the present exemplary embodiment, in a cross section taken along an A-A' direction (diagonal directions of the pixel), the seventh semiconductor region 317 and the ninth semiconductor region 319 extend from the light incidence surface side into the side of the surface facing the light incidence surface. On the other hand, in a cross section taken along a B-B' direction (the opposite side direction of the pixel), the seventh semiconductor region 317 extending up to the surface facing the light incidence surface is not included, and the seventh semiconductor region 317 and the tenth semiconductor region 320 are separated. The tenth semiconductor region 320 formed in place causes an electric field in the traverse direction to collect dark charges generated at corner portions of the pixel into the first semiconductor region 311, through which the dark charges are easily discharged without passing through a strong electric field region inducing avalanche multiplication, reducing the DCR.

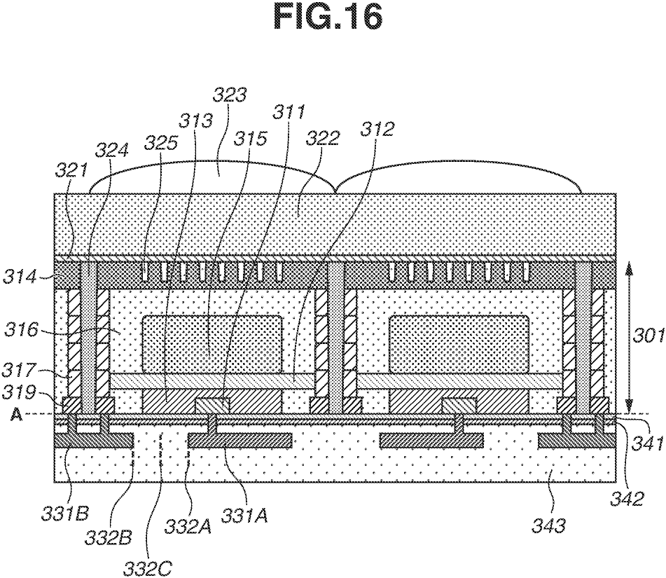

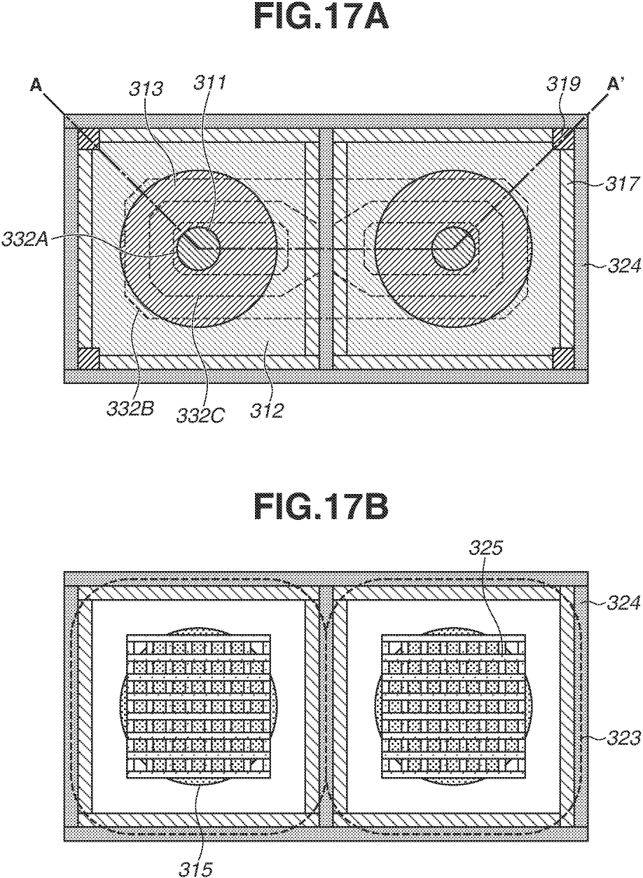

A photoelectric conversion apparatus according to a fourth exemplary embodiment will be described with reference to FIGS. 16, 17A, and 17B.

The descriptions common to those in the first to third exemplary embodiments will be omitted, and the difference from the first exemplary embodiment will be mainly described. In the first exemplary embodiment, the anode wire is symmetrically extended, but in the present exemplary embodiment, an anode wire is extended in a specific direction alone.

FIG. 16 is a cross-sectional view illustrating the photoelectric conversion elements 102 of the photoelectric conversion apparatus according to the fourth exemplary embodiment that correspond to two pixels in the direction vertical to the surface direction of a substrate, and corresponds to an A-A' cross section in FIG. 17A. In a certain direction, the anode wire 331B satisfies a relationship in which the virtual line 332C and the third semiconductor region 313 overlap each other in a planar view, and in another direction, the anode wire 331B does not satisfy the relationship.

FIGS. 17A and 17B are pixel plan views each illustrating two pixels of the photoelectric conversion apparatus according to the fourth exemplary embodiment.

FIG. 17A is a plan view illustrating two pixels in sight of the surface facing the light incidence surface in a planar view. FIG. 17B is a plan view illustrating two pixels in sight of the light incidence surface side in a planar view. The cathode wire 331A of the photoelectric conversion element 102 on the left side has a shape protruding rightward from the center of the photoelectric conversion element 102, and the cathode wire 331A of the photoelectric conversion element 102 on the right side has a shape protruding leftward from the center of the photoelectric conversion element 102. The anode wire 331B of the photoelectric conversion elements 102 is shared by the left and right photoelectric conversion elements 102, and at least part of the inner circumferential portion 332B includes a hole overlapping the respective third semiconductor regions 313 of the left and right photoelectric conversion elements 102. The virtual line 332C partially overlaps the third semiconductor regions 313 in a planar view.

Such a configuration allows the distance between the cathode wires 331A of neighboring pixels to be shortened, facilitating an easy miniaturization of the pixels.

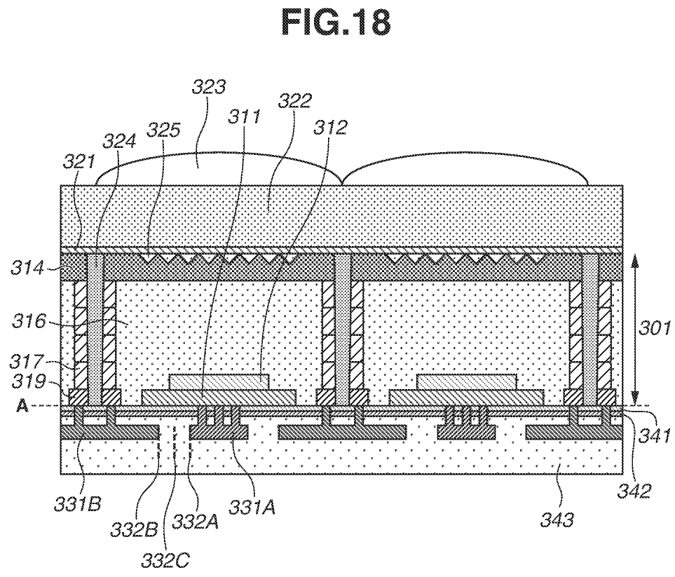

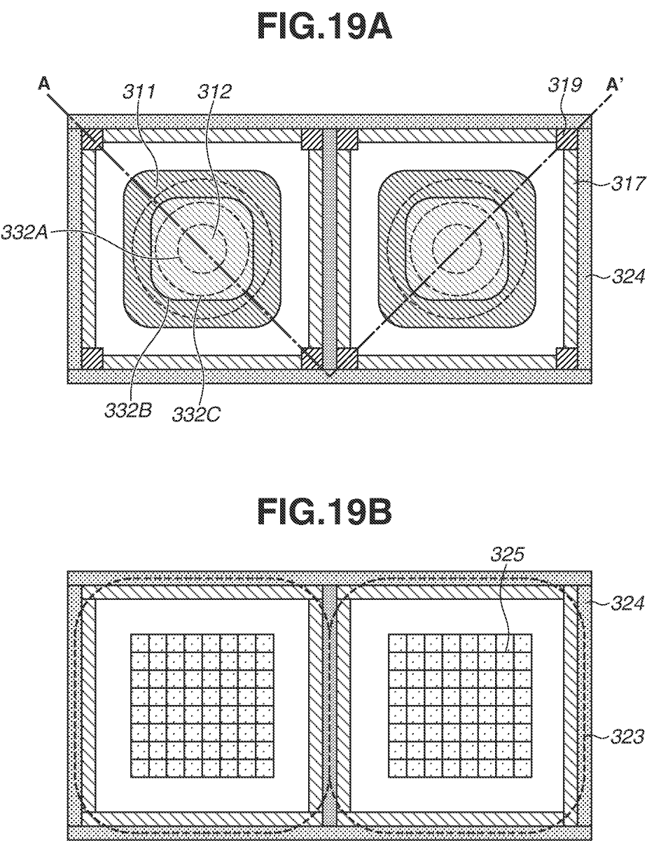

A photoelectric conversion apparatus according to a fifth exemplary embodiment will be described with reference to FIGS. 18, 19A, and 19B.

The descriptions common to those in the first to fourth exemplary embodiments will be omitted, and the difference from the first exemplary embodiment will be mainly described.

FIG. 18 is a cross-sectional view illustrating the photoelectric conversion elements 102 of the photoelectric conversion apparatus according to the fifth exemplary embodiment that correspond to two pixels in the direction vertical to the surface direction of a substrate, and corresponds to an A-A' cross section in FIG. 19A. In the photoelectric conversion apparatus according to the present exemplary embodiment, the N-type first semiconductor region 311 occupies a large portion of the light receiving surface of a pixel, and the area of the P-type second semiconductor region 312 with respect to the light receiving surface of the pixel is small, compared with the photoelectric conversion apparatus according to the first exemplary embodiment.

Incident light is subjected to avalanche multiplication in an avalanche multiplication region formed between the first semiconductor region 311 and the second semiconductor region 312. Thus, in a case where the opening of a pixel is designed in such a manner that the first semiconductor region 311 and the second semiconductor region 312 are exposed to light, the opening ratio of the photoelectric conversion apparatus according to the present exemplary embodiment is smaller than the opening ratios of the photoelectric conversion apparatuses according to the first to fourth exemplary embodiments. A smaller opening ratio reduces the volume of a photoelectric conversion region from which signals are detectable, reducing crosstalk.

The recess and protrusion structure 325 has a square pyramid shape in which its cross section is a triangular shape with its bottom surface corresponding to the light incidence surface. Such a recess and protrusion structure 325 can be formed by etching along a crystal surface, providing a high manufacturing stability.

In the photoelectric conversion apparatus according to the present exemplary embodiment, a high concentration of nitrogen (N) is implanted into the front surface of the first semiconductor region 311. This therefore allows easier block of the influence of potential changes caused by hot carriers being implanted onto the surface of the first semiconductor region 311, reducing the temporal change in breakdown voltage.

FIGS. 19A and 19B are pixel plan views each illustrating two pixels of the photoelectric conversion apparatus according to the fifth exemplary embodiment. FIG. 19A is a plan view illustrating two pixels in sight of the surface facing the light incidence surface in a planar view. FIG. 19B is a plan view illustrating two pixels in sight of the light incidence surface side in a planar view.

In the photoelectric conversion apparatus illustrated in FIGS. 19A and 19B, the region of the first semiconductor region 311 that does not overlap the second semiconductor region 312 in a planar view functions as an electric field mitigation region and surrounds an avalanche multiplication region. At least part of the boundary with an insulating film that faces the cathode wire 331A overlaps the electric field mitigation region in a planar view. In addition, the virtual line 332C entirely overlaps the first semiconductor region 311 in a planar view, and at least partially overlaps this charge mitigation region in a planar view.

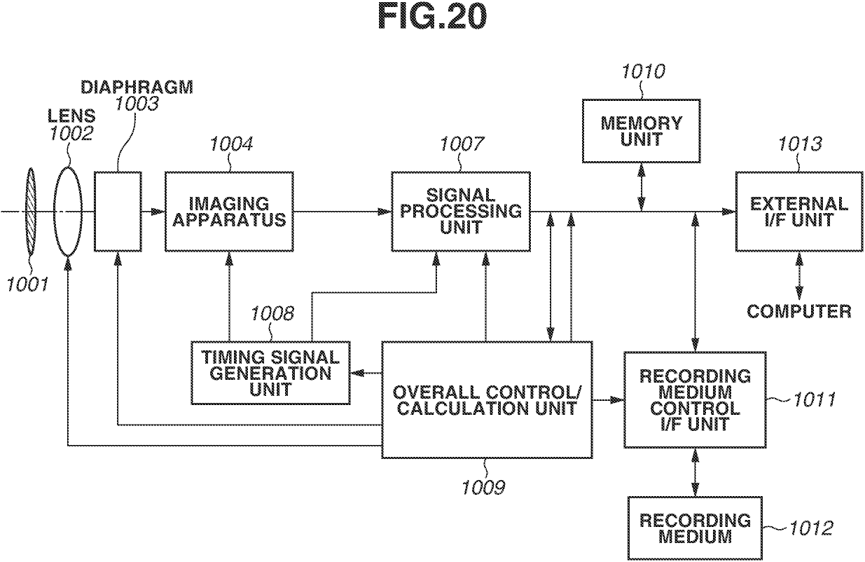

A photoelectric conversion system according to the present exemplary embodiment will be described with reference to FIG. 20. FIG. 20 is a block diagram illustrating a schematic configuration of the photoelectric conversion system according to the present exemplary embodiment.

The photoelectric conversion apparatuses described in the above-described first to sixth exemplary embodiments can be applied to various photoelectric conversion systems. Examples of photoelectric conversion systems to which the photoelectric conversion apparatus can be applied include a digital still camera, a digital camcorder, a monitoring camera, a copier, a facsimile, a mobile phone, an in-vehicle camera, and an observation satellite. A camera module including an optical system such as a lens, and an imaging apparatus is also included in the photoelectric conversion systems. As an example of these photoelectric conversion systems, FIG. 20 exemplarily illustrates the block diagram of a digital still camera.

The photoelectric conversion system exemplified in FIG. 20 includes an imaging apparatus 1004 serving as an example of the photoelectric conversion apparatus, and a lens 1002 that forms an optical image of a subject on the imaging apparatus 1004. The photoelectric conversion system further includes a diaphragm 1003 for varying the quantity of light passing through the lens 1002, and a barrier 1001 for protecting the lens 1002. The lens 1002 and the diaphragm 1003 serve as an optical system that condenses light onto the imaging apparatus 1004. The imaging apparatus 1004 is the photoelectric conversion apparatus according to any of the above-described exemplary embodiments, and converts an optical image formed by the lens 1002 into an electric signal.

The photoelectric conversion system further includes a signal processing unit 1007 serving as an image generation unit that generates an image by processing an output signal output by the imaging apparatus 1004. The signal processing unit 1007 performs an operation of outputting image data after performing various types of correction and compression as appropriate. The signal processing unit 1007 may be formed on a semiconductor substrate on which the imaging apparatus 1004 is provided, or may be formed on a semiconductor substrate different from that of the imaging apparatus 1004.

The photoelectric conversion system further includes a memory unit 1010 for temporarily storing image data, and an external interface unit (external I/F unit) 1013 for communicating with an external computer. The photoelectric conversion system further includes a recording medium 1012 such as a semiconductor memory for recording or reading out captured image data, and a recording medium control interface unit (recording medium control I/F unit) 1011 for performing recording onto or readout from the recording medium 1012. The recording medium 1012 may be built into the photoelectric conversion system, or may be detachably attached to the photoelectric conversion system.

The photoelectric conversion system further includes an overall control/calculation unit 1009 that generally controls various types of calculation and the digital still camera, and a timing signal generation unit 1008 that outputs various timing signals to the imaging apparatus 1004 and the signal processing unit 1007. The timing signals may be input from the outside. The photoelectric conversion system is only required to include at least the imaging apparatus 1004 and the signal processing unit 1007 that processes an output signal output from the imaging apparatus 1004.

The imaging apparatus 1004 outputs an imaging signal to the signal processing unit 1007. The signal processing unit 1007 outputs image data after performing predetermined signal processing on the imaging signal output from the imaging apparatus 1004. The signal processing unit 1007 generates an image using the imaging signal.

In this manner, according to the present exemplary embodiment, a photoelectric conversion system to which the photoelectric conversion apparatus (imaging apparatus) according to any of the above-described exemplary embodiments is applied can be implemented.

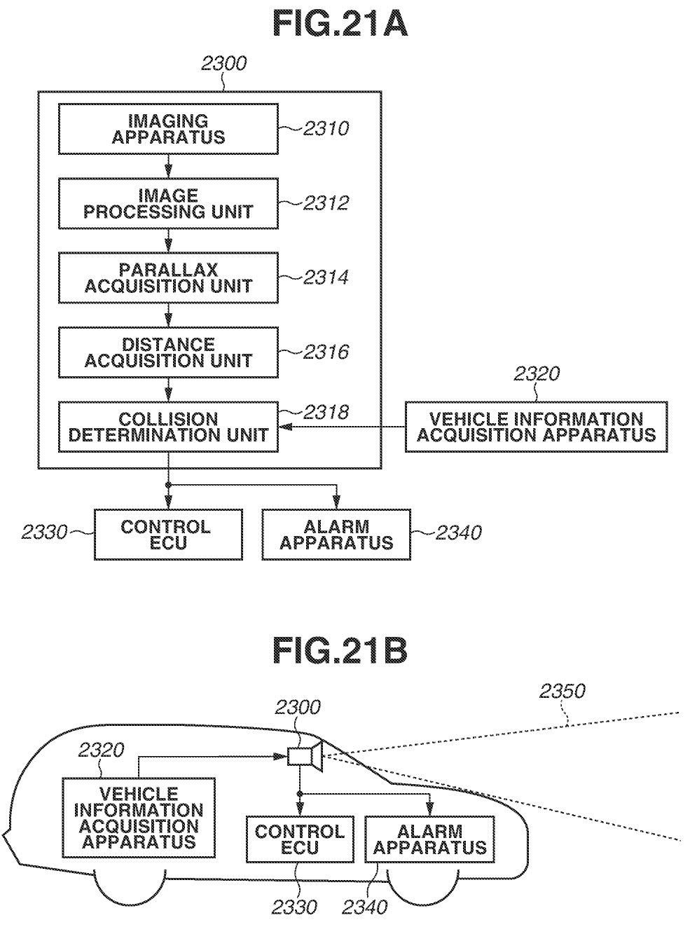

A photoelectric conversion system and a movable body according to the present exemplary embodiment will be described with reference to FIGS. 21A and 21B. FIGS. 21A and 21B are diagrams illustrating configurations of the photoelectric conversion system and the movable body according to the present exemplary embodiment.

FIG. 21A illustrates an example of a photoelectric conversion system related to an in-vehicle camera. A photoelectric conversion system 2300 includes an imaging apparatus 2310. The imaging apparatus 2310 is the photoelectric conversion apparatus according to any of the above-described exemplary embodiments. The photoelectric conversion system 2300 includes an image processing unit 2312 that performs image processing on a plurality of pieces of image data acquired by the imaging apparatus 2310. The photoelectric conversion system 2300 further includes a parallax acquisition unit 2314 that calculates the parallax (phase difference between parallax images) from the plurality of pieces of image data acquired by the photoelectric conversion system 2300. The photoelectric conversion system 2300 further includes a distance acquisition unit 2316 that calculates the distance to a target object based on the calculated parallax, and a collision determination unit 2318 that determines whether collision is likely to occur, based on the calculated distance. In this example, the parallax acquisition unit 2314 and the distance acquisition unit 2316 serve as an example of a distance information acquisition unit that acquires distance information regarding the distance to a target object. More specifically, the distance information is information regarding a parallax, the amount of defocus, and the distance to a target object. The collision determination unit 2318 may determine collision likelihood using any of these pieces of distance information. The distance information acquisition unit may be implemented by dedicatedly-designed hardware, or may be implemented by a software module.

Alternatively, the distance information acquisition unit may be implemented by a field programmable gate array (FPGA) or an application specific integrated circuit (ASIC), or may be implemented by a combination of these.

The photoelectric conversion system 2300 is connected with a vehicle information acquisition apparatus 2320, and can acquire vehicle information such as vehicle speed, a yaw rate, or a rudder angle. In addition, a control electronic control unit (ECU) 2330 is connected to the photoelectric conversion system 2300. The ECU 2330 serves as a control unit that outputs a control signal for causing a vehicle to generate braking force, based on a determination result obtained by the collision determination unit 2318. The photoelectric conversion system 2300 is also connected with an alarm apparatus 2340 that raises an alarm to a driver based on a determination result obtained by the collision determination unit 2318. For example, if the determination result obtained by the collision determination unit 2318 indicates a high collision likelihood, the control ECU 2330 performs vehicle control for avoiding collision or reducing damage by braking, releasing a gas pedal, or reducing engine output. The alarm apparatus 2340 issues an alarm to a user by sounding an alarm such as warning sound, displaying warning information on the screen of a car navigation system, or vibrating the seatbelt or the steering wheel.

In the present exemplary embodiment, the photoelectric conversion system 2300 captures images of the periphery of the vehicle such as the front side or the rear side, for example. FIG. 21B illustrates the photoelectric conversion system 2300 for capturing an image of the vehicle front side (imaging range 2350). The vehicle information acquisition apparatus 2320 issues instructions to the photoelectric conversion system 2300 or the imaging apparatus 2310. Such a configuration provides a higher accuracy of distance measurement.

The above description has been given of an example in which control is performed in such a manner as not to collide with another vehicle. The photoelectric conversion system can also be applied to the control for performing automatic operation by following another vehicle, or the control for performing automatic operation in such a manner as not to deviate from a lane. Furthermore, the photoelectric conversion system can be applied to a movable body (moving apparatus) such as a vessel, an aircraft, or an industrial robot aside from a vehicle such as an automobile. Moreover, the photoelectric conversion system can be applied to a device that extensively uses object recognition, such as an intelligent transport system (ITS), in addition to a movable body.

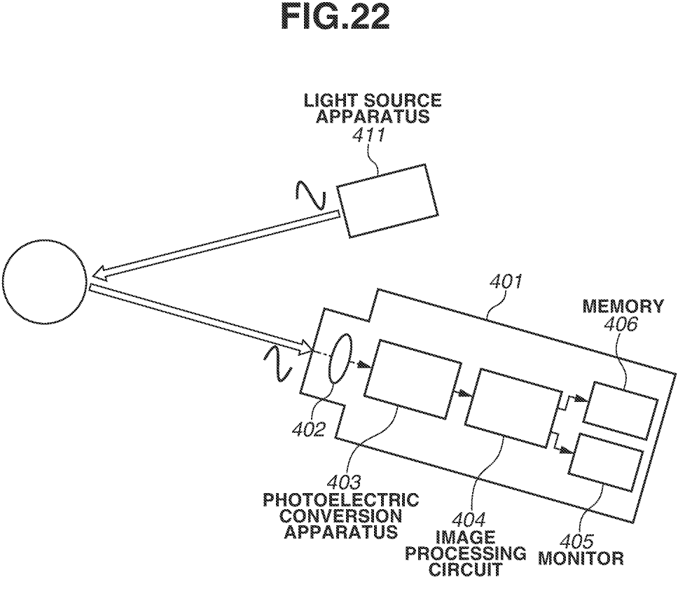

A photoelectric conversion system according to the present exemplary embodiment will be described with reference to FIG. 22. FIG. 22 is a block diagram illustrating a configuration example of a distance image sensor serving as the photoelectric conversion system according to the present exemplary embodiment.

As illustrated in FIG. 22, a distance image sensor 401 includes an optical system 402, a photoelectric conversion apparatus 403, an image processing circuit 404, a monitor 405, and a memory 406. Then, the distance image sensor 401 can acquire a distance image corresponding to the distance to a subject, by receiving light (modulated light or pulse light) that has been projected from a light source apparatus 411 toward the subject, and reflected on the front surface of the subject.

The optical system 402 includes one or a plurality of lenses, and forms an image on the light receiving surface (sensor portion) of the photoelectric conversion apparatus 403 by guiding image light (incident light) from the subject to the photoelectric conversion apparatus 403.

The photoelectric conversion apparatus according to any of the above exemplary embodiments is applied to the photoelectric conversion apparatus 403, and a distance signal indicating the distance obtained from a light receiving signal output from the photoelectric conversion apparatus 403 is supplied to the image processing circuit 404.

The image processing circuit 404 performs image processing of constructing a distance image, based on the distance signal supplied from the photoelectric conversion apparatus 403. Then, the distance image (image data) obtained by the image processing is supplied to the monitor 405 and displayed thereon, or supplied to the memory 406 and stored (recorded) therein.

The distance image sensor 401 with the above-described configuration including the above-described photoelectric conversion apparatus can acquire a more accurate distance image with characteristic enhancement of a pixel, for example.

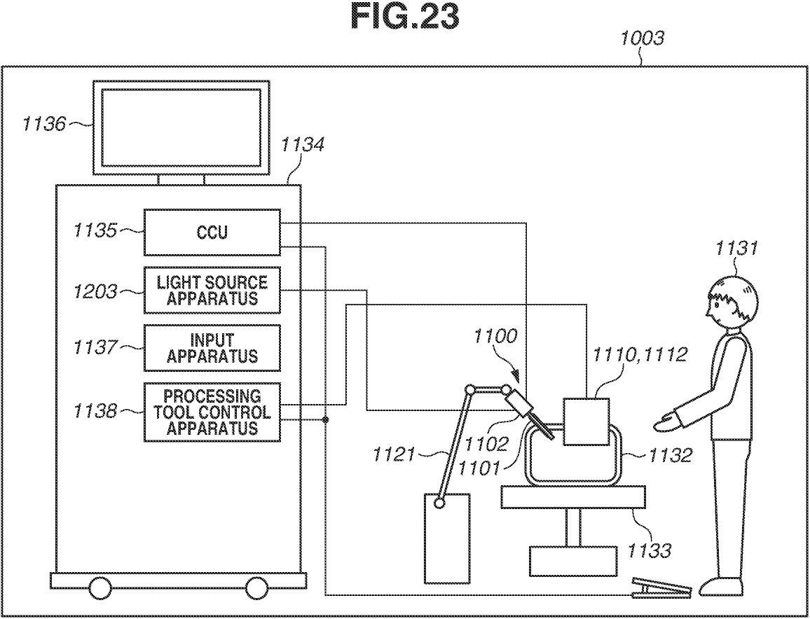

A photoelectric conversion system according to the present exemplary embodiment will be described with reference to FIG. 23. FIG. 23 is a diagram illustrating an example of a schematic configuration of an endoscopic operation system serving as a photoelectric conversion system of the present exemplary embodiment.

FIG. 23 illustrates a state in which an operator (doctor) 1131 is performing operation on a patient 1132 lying on a patient bed 1133, using an endoscopic operation system 1150. As illustrated in FIG. 23, the endoscopic operation system 1150 includes an endoscope 1100, a surgical tool 1110, and a cart 1134 equipped with various apparatuses for endoscopic operation.

The endoscope 1100 includes a lens barrel 1101 having a region to be inserted into a body cavity of the patient 1132 by a predetermined length from the distal end, and a camera head 1102 connected to the proximal end of the lens barrel 1101. In the example illustrated in FIG. 23, the endoscope 1100 formed as a so-called rigid scope including the rigid lens barrel 1101 is illustrated, but the endoscope 1100 may be formed as a flexible scope including a so-called flexible lens barrel.

An opening portion in which an objective lens is fitted is provided at the distal end of the lens barrel 1101. A light source apparatus 1203 is connected to the endoscope 1100, and light generated by the light source apparatus 1203 is guided to the distal end of the lens barrel 1101 by a light guide extended inside the lens barrel 1101, and emitted onto an observation target in a body cavity of the patient 1132 via the objective lens. The endoscope 1100 may be a direct view endoscope, or may be an oblique view endoscope or a lateral view endoscope.

An optical system and a photoelectric conversion apparatus are provided inside the camera head 1102. Reflected light (observation light) from the observation target is condensed by the optical system to the photoelectric conversion apparatus. The observation light is photoelectrically-converted by the photoelectric conversion apparatus, and an electric signal corresponding to the observation light (i.e., image signal corresponding to an observed image) is generated. The photoelectric conversion apparatus according to any of the above exemplary embodiments can be used as the photoelectric conversion apparatus. The image signal is transmitted to a camera control unit (CCU) 1135 as RAW data.

The CCU 1135 includes a central processing unit (CPU) or a graphics processing unit (GPU), and comprehensively controls operations of the endoscope 1100 and a display device 1136. Furthermore, the CCU 1135 receives an image signal from the camera head 1102, and performs various types of image processing for displaying an image based on the image signal, such as development processing (demosaic processing) on the image signal.

Based on the control from the CCU 1135, the display device 1136 displays an image based on the image signal on which image processing has been performed by the CCU 1135.

The light source apparatus 1203 includes a light source such as a light emitting diode (LED), and supplies irradiation light for capturing an image of an operative site, to the endoscope 1100.

An input apparatus 1137 is an input interface for the endoscopic operation system 1150. A user can input various types of information and instructions to the endoscopic operation system 1150 via the input apparatus 1137.

A processing tool control apparatus 1138 controls the driving of an energy processing tool 1112 for cauterizing or cutting a tissue, or sealing a blood vessel.

The light source apparatus 1203 that emits irradiation light for capturing an image of an operative site, to the endoscope 1100 can include, for example, an LED, a laser light source, or a white light source constituting a combination of these. With a white light source constituting a combination of RGB laser light sources, output intensity and an output timing of each color (each wavelength) can be controlled with high accuracy, which allows the adjustment of white balance of a captured image in the light source apparatus 1203. In this case, by emitting laser light from each RGB laser light source onto an observation target in a time division manner, and controlling the driving of an image sensor of the camera head 1102 in synchronization with the emission timing, an image corresponding to each of RGB can be captured in a time division manner. This method provides a color image without a color filter in the image sensor.

The driving of the light source apparatus 1203 may be controlled in such a manner as to change the intensity of light to be output, every predetermined time. Acquiring images in a time division manner by controlling the driving of the image sensor of the camera head 1102 in synchronization with the change timing of the light intensity, and combining the images allows a high dynamic range image to be produced without so-called blocked up shadows and clipped whites.

The light source apparatus 1203 may be configured to supply light in a predetermined wavelength band adapted to special light observation. In the special light observation, for example, wavelength dependency of light absorption in body tissues is utilized. Specifically, with light emitted in a narrower band compared with irradiation light (i.e., white light) in normal observation, an image of a predetermined tissue such as a blood vessel in a superficial portion of a mucous membrane is captured with high contrast.

Alternatively, in special light observation, fluorescent observation of obtaining an image with fluorescence generated by emitting excitation light may be performed. In fluorescent observation, fluorescence from a body tissue irradiated with excitation light can be observed, or a fluorescent image can be obtained by locally injecting reagent such as indocyanine green (ICG) into a body tissue and emitting excitation light suitable for the fluorescence wavelength of the reagent onto the body tissue. The light source apparatus 1203 can be configured to emit narrow-band light and/or excitation light adapted to such special light observation.

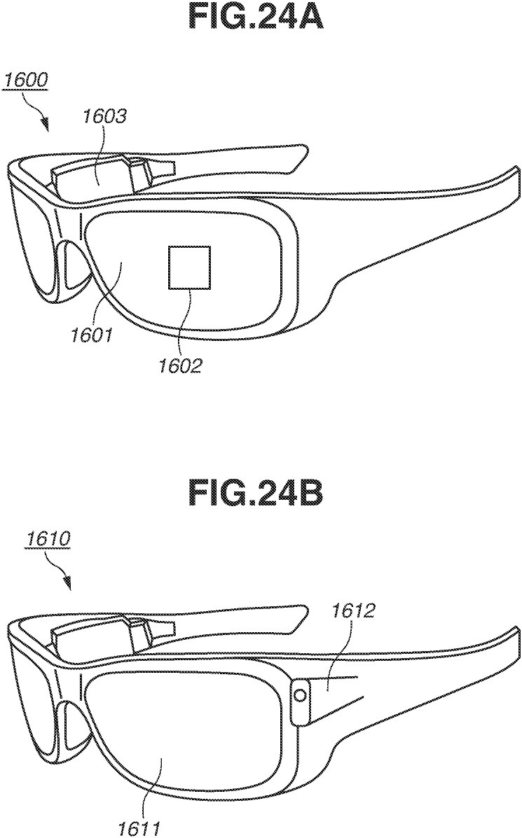

A photoelectric conversion system according to the present exemplary embodiment will be described with reference to FIGS. 24A and 24B. FIG. 24A illustrates eyeglasses 1600 (smart glasses) serving as a photoelectric conversion system according to the present exemplary embodiment. The eyeglasses 1600 include a photoelectric conversion apparatus 1602. The photoelectric conversion apparatus 1602 is the photoelectric conversion apparatus described in any of the above-described exemplary embodiments. A display device including a light emission device such as an organic light emitting diode (OLED) or an LED may be provided on the back surface side of a lens 1601. The number of photoelectric conversion apparatuses 1602 may be one or plural. A plurality of types of photoelectric conversion apparatuses may be used in combination. The arrangement position of the photoelectric conversion apparatus 1602 is not limited to the position illustrated in FIG. 24A.

The eyeglasses 1600 further include a control apparatus 1603. The control apparatus 1603 functions as a power source that supplies power to the photoelectric conversion apparatus 1602 and the above-described display device. The control apparatus 1603 controls operations of the photoelectric conversion apparatus 1602 and the display device. The lens 1601 includes an optical system for condensing light to the photoelectric conversion apparatus 1602.

FIG. 24B illustrates eyeglasses 1610 (smart glasses) according to one application example. The eyeglasses 1610 include a control apparatus 1612, and the control apparatus 1612 is equipped with a photoelectric conversion apparatus equivalent to the photoelectric conversion apparatus 1602, and a display device. A lens 1611 includes an optical system for projecting light emitted from the photoelectric conversion apparatus and the display device in the control apparatus 1612, and an image is projected onto the lens 1611. The control apparatus 1612 functions as a power source that supplies power to the photoelectric conversion apparatus and the display device, and controls operations of the photoelectric conversion apparatus and the display device. The control apparatus may include a line-of-sight detection unit that detects the line-of-sight of a wearer. Infrared light may be used for the detection of the line-of-sight. An infrared light emission unit emits infrared light onto the eyeball of a user looking at a displayed image. An imaging unit including a light receiving element detects reflected light of the emitted infrared light that has been reflected from the eyeball. A captured image of the eyeball is thereby obtained. A reduction unit for reducing light traveling from the infrared light emission unit to a display unit in a planar view prevents image quality from degrading.

From the captured image of the eyeball obtained by the image capturing using infrared light, the line-of-sight of the user on the displayed image is detected. A known method that uses a captured image of an eyeball can be applied to the line-of-sight detection. As an example, a line-of-sight detection method that is based on a Purkinje image obtained by reflection of irradiation light on a cornea can be used.

More specifically, line-of-sight detection processing that is based on the pupil center corneal reflection is performed. The eye vector representing the direction (rotational angle) of an eyeball is calculated based on an image of a pupil and a Purkinje image that are included in a captured image of an eyeball, using the pupil center corneal reflection, and the line-of-sight of a user is detected.

The display device of the present exemplary embodiment may include the photoelectric conversion apparatus including a light receiving element, and a displayed image of the display device may be controlled based on the-line-of-sight information about the user from the photoelectric conversion apparatus.

Specifically, in the display device, a first eyeshot region viewed by the user, and a second eyeshot region other than the first eyeshot region are determined based on the line-of-sight information. The first eyeshot region and the second eyeshot region may be determined by a control apparatus of the display device, or the first eyeshot region and the second eyeshot region determined by an external control apparatus may be received. In a display region of the display device, the display resolution of the first eyeshot region may be controlled to be higher than the display resolution of the second eyeshot region. In other word, the resolution of the second eyeshot region may be made lower than the resolution of the first eyeshot region.

The display region includes a first display region and a second display region different from the first display region. Based on the line-of-sight information, a region with high priority may be determined from between the first display region and the second display region. The first display region and the second display region may be determined by a control apparatus of the display device, or the first display region and the second display region determined by an external control apparatus may be received. The resolution of a region with high priority may be controlled to be higher than the resolution of a region other than the region with high priority. In other words, the resolution of a region with relatively-low priority may be set to a low resolution.

Artificial intelligence (AI) may be used in determining the first eyeshot region and the region with high priority. The AI may be a model configured to estimate the angle of a line-of-sight, and the distance to a target existing at the end of the line-of-sight, from an image of the eyeball using teaching data including an image of an eyeball, and the direction in which the eyeball in the image actually gives a gaze. An AI program may be included in the display device, in the photoelectric conversion apparatus, or in an external apparatus. An AI program included in an external apparatus is transmitted to the display device via communication.

In display control performed based on visual detection, the present invention can be suitably applied to smart glasses further including a photoelectric conversion apparatus that captures an image of the outside. The smart glasses can display external information obtained by image capturing, in real time.

### Modified Exemplary Embodiment

The present invention is not limited to the above-described exemplary embodiments, and various modifications can be made.

For example, an example in which a partial configuration of an exemplary embodiment is added to another exemplary embodiment, and an example in which a partial configuration of an exemplary embodiment is replaced with a partial configuration of another exemplary embodiment are also included in the exemplary embodiments of the present invention.

The photoelectric conversion systems described in the above-described sixth and seventh exemplary embodiments are examples of photoelectric conversion systems to which a photoelectric conversion apparatus can be applied, and a photoelectric conversion system to which a photoelectric conversion apparatus according to an exemplary embodiment of the present invention can be applied is not limited to the configurations illustrated in FIGS. 20 and 21A and 21B. The same applies to the ToF system described in the eighth exemplary embodiment, the endoscope described in the ninth exemplary embodiment, and the smart glasses described in the tenth exemplary embodiment.

Each of the above-described exemplary embodiments merely indicates a specific example in implementing the present invention, and the technical scope of the present invention is not to be understood in a limiting manner based on these. In other words, exemplary embodiments of the present invention can be implemented in various forms without departing from the technical idea or major features thereof.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-154432, filed Sep. 22, 2021, which is hereby incorporated by reference herein in its entirety.

What is claimed is:

1. A photoelectric conversion apparatus comprising:
an avalanche diode arranged in a semiconductor layer having a first surface and a second surface facing the first surface,
wherein the avalanche diode includes:
a first semiconductor region of a first conductivity type, which is arranged at a first depth,
a second semiconductor region of a second conductivity type, which is arranged at a second depth deeper than the first depth with respect to the second surface,
a third semiconductor region provided in contact with an end of the first semiconductor region in a planar view from the second surface,
a first wiring portion connected to the first semiconductor region, and
a second wiring portion connected to the second semiconductor region, and
wherein, in a planar view from the second surface, at least part of a boundary between an insulating film and the second wiring portion that faces the first wiring portion overlaps the third semiconductor region and does not overlap the first semiconductor region.

2. A photoelectric conversion apparatus comprising:
a plurality of avalanche diodes arranged in a semiconductor layer having a first surface and a second surface facing the first surface,
wherein the avalanche diode includes:
a first semiconductor region of a first conductivity type, which is arranged at a first depth,
a second semiconductor region of a second conductivity type, which is arranged at a second depth deeper than the first depth with respect to the second surface,
a third semiconductor region provided in contact with an end of the first semiconductor region in a planar view from the second surface,
a first wiring portion connected to the first semiconductor region, and
a second wiring portion connected to the second semiconductor region, and
wherein, in a planar view from the second surface, at least part of a line internally dividing, into equal distances, a distance between a boundary between the first wiring portion and an insulating film and a boundary between the second wiring portion and the insulating film overlaps the third semiconductor region and does not overlap the first semiconductor region.

3. The photoelectric conversion apparatus according to claim 1, wherein, in a planar view from the second surface, an area of the first semiconductor region is smaller than an area of the third semiconductor region.

4. The photoelectric conversion apparatus according to claim 1, wherein an impurity concentration in the third semiconductor region is lower than an impurity concentration in the first semiconductor region.

5. A photoelectric conversion apparatus comprising:
an avalanche diode arranged in a semiconductor layer having a first surface and a second surface facing the first surface,
wherein the avalanche diode includes:
a first semiconductor region of a first conductivity type, which is arranged at a first depth,
an avalanche multiplication region formed between the first semiconductor region and a second semiconductor region of a second conductivity type, which is arranged at a second depth deeper than the first depth with respect to the second surface,
an electric field mitigation region surrounding the avalanche multiplication region in a planar view from the second surface,
a first wiring portion connected to the first semiconductor region, and
a second wiring portion connected to the second semiconductor region, and
wherein, in a planar view from the second surface, at least part of a boundary between an insulating film and the second wiring portion that faces the first wiring portion overlaps the electric field mitigation region.

6. A photoelectric conversion apparatus comprising:
an avalanche diode arranged in a semiconductor layer having a first surface and a second surface facing the first surface,
wherein the avalanche diode includes:
a first semiconductor region of a first conductivity type, which is arranged at a first depth,
an avalanche multiplication region formed between the first semiconductor region and a second semiconductor region of a second conductivity type, which is arranged at a second depth deeper than the first depth with respect to the second surface,
an electric field mitigation region surrounding the avalanche multiplication region in a planar view from the second surface,
a first wiring portion connected to the first semiconductor region, and
a second wiring portion connected to the second semiconductor region, and
wherein, in a planar view from the second surface, at least part of a line internally dividing, into equal distances, a distance between a boundary between the first wiring portion and an insulating film, and a boundary between the second wiring portion and the insulating film overlaps the electric field mitigation region.

7. The photoelectric conversion apparatus according to claim 5, wherein, in a planar view from the second surface, an area of the first semiconductor region is smaller than an area of the electric field mitigation region.

8. The photoelectric conversion apparatus according to claim 1,
wherein the first wiring portion and the second wiring portion are formed in a plurality of wiring layers stacked on a side of the second surface, and
wherein the second wiring portion is formed in a wiring layer that is a wiring layer farther from the second surface than a contact connecting the first semiconductor region and the first wiring portion, and that is a wiring layer closest to the second surface among the plurality of wiring layers.

9. The photoelectric conversion apparatus according to claim 1, wherein the first wiring portion and the second wiring portion are formed in a same wiring layer stacked on a side of the second surface.

10. The photoelectric conversion apparatus according to claim 1, wherein a distance from the second surface to the second wiring portion in a direction vertical to the second surface is shorter than a distance from the first wiring portion to the second wiring portion in a direction horizontal to the second surface.

11. The photoelectric conversion apparatus according to claim 1, wherein the first surface is a light incidence surface.

12. The photoelectric conversion apparatus according to claim 1, wherein, in a planar view from the second surface, the second wiring portion surrounds a perimeter of the first wiring portion.

13. The photoelectric conversion apparatus according to claim 1, wherein, in a planar view from the second surface, the first semiconductor region is encompassed by the second semiconductor region.

14. The photoelectric conversion apparatus according to claim 1, wherein a fourth semiconductor region of the second conductivity type, which is arranged at a third depth deeper than the second depth with respect to the second surface, is included.

15. The photoelectric conversion apparatus according to claim 14,
wherein a fifth semiconductor region of the first conductivity type is provided between the second semiconductor region and the fourth semiconductor region, and
wherein an impurity concentration of the first conductivity type in the fifth semiconductor region is lower than an impurity concentration of the first conductivity type in the first semiconductor region.

16. The photoelectric conversion apparatus according to claim 15, wherein a potential difference between the first semiconductor region and the second semiconductor region is larger than a potential difference between the second semiconductor region and the fifth semiconductor region.

17. The photoelectric conversion apparatus according to claim 1,
wherein the photoelectric conversion apparatus includes a plurality of the avalanche diodes,
wherein the plurality of avalanche diodes includes a first avalanche diode and a second avalanche diode adjacent to the first avalanche diode, and
wherein a pixel isolation portion is included between the first avalanche diode and the second avalanche diode.

18. The photoelectric conversion apparatus according to claim 17,
wherein the plurality of avalanche diodes includes a third avalanche diode adjacent to the second avalanche diode,
wherein a first pixel isolation portion is included between the first avalanche diode and the second avalanche diode,
wherein a second pixel isolation portion is included between the second avalanche diode and the third avalanche diode, and
wherein the second semiconductor region in the second avalanche diode extends up to the second pixel isolation portion from the first pixel isolation portion in a cross section vertical to the first surface.

19. The photoelectric conversion apparatus according to claim 1, wherein the semiconductor layer includes an oxidized film and a nitride film that are stacked on the second surface.

20. The photoelectric conversion apparatus according to claim 1, wherein the semiconductor layer includes a plurality of recess and protrusion structures provided in the first surface.

21. The photoelectric conversion apparatus according to claim 20, wherein at least part of a boundary of the second wiring portion that faces the first wiring portion is encompassed by a region in which the plurality of recess and protrusion structures is formed, in a planar view from the second surface.

22. A photoelectric conversion system comprising:
the photoelectric conversion apparatus according to claim 1, and
a signal processing unit configured to generate an image using a signal output by the photoelectric conversion apparatus.

23. A movable body including the photoelectric conversion apparatus according to claim 1, the movable body comprising:
a control unit configured to control a movement of the movable body using a signal output by the photoelectric conversion apparatus.
